(19) United States
(12) Patent Application Publication
(10) Pub. No.: US 2026/0013091 A1
(43) Pub. Date: Jan. 8, 2026

(54) ELECTRONIC DEVICE INCLUDING STRUCTURE FOR HEAT DISSIPATION

(71) Applicant: SAMSUNG ELECTRONICS CO., LTD., Suwon-si (KR)

(72) Inventors: Joseph Ahn, Suwon-si (KR); Hyunho Shin, Suwon-si (KR); Haejin Lee, Suwon-si (KR)

(73) Assignee: SAMSUNG ELECTRONICS CO., LTD., Suwon-si (KR)

(21) Appl. No.: 19/225,689

(22) Filed: Jun. 2, 2025

Related U.S. Application Data
(63) Continuation of application No. PCT/KR2025/006135, filed on May 8, 2025.

(30) Foreign Application Priority Data
Jul. 4, 2024 (KR) 10-2024-0088539
Jul. 8, 2024 (KR) 10-2024-0089992

(51) Int. Cl. H05K 7/20; H04M 1/02

(52) U.S. Cl. CPC H05K 7/20981; H04M 1/0222; H04M 1/0262; H04M 1/0277; H05K 7/20963

(57) ABSTRACT

An electronic device may include: a bracket including a mounting portion; a printed circuit board (PCB) overlapping with the bracket; a heat generating component on a surface of the PCB, the surface of the PCB facing the bracket; a battery spaced apart from the heat generating component, the battery being in the bracket; and a vapor chamber on the mounting portion of the bracket, wherein the vapor chamber includes: a first portion above the heat generating component, a second portion between the mounting portion and the battery, and a third portion extending from the first portion of the vapor chamber to the second portion of the vapor chamber.

### CROSS-REFERENCE TO RELATED APPLICATIONS

This application is a continuation of International Application No. PCT/KR2025/006135, designating the United States, filed on May 8, 2025, in the Korean Intellectual Property Receiving Office, and claiming priority to Korean Patent Application Nos. 10-2024-0088539 filed on Jul. 4, 2024, and 10-2024-0089992 filed on Jul. 8, 2024, in the Korean Intellectual Property Office, the disclosures of each of which are incorporated by reference herein in their entireties.

### BACKGROUND

### 1. Field

Some embodiments of the present disclosure relate to an electronic device including a structure for heat dissipation.

### 2. Description of Related Art

Electronic devices may include various electronic components. The electronic devices may be downsized such that they may be worn by a user or carried by the user. While electronic components disposed in such a downsized electronic device operate to respond to a user's request, heat may be generated in the electronic device. The electronic devices may be required to have a structure for dissipating heat generated therein.

The above information is presented as background information only to assist with understanding of the present disclosure. No determination has been made, and no assertion is made, as to whether any of the above might be applicable as prior art with regard to the present disclosure.

### SUMMARY

An electronic device is provided. The electronic device may include a bracket including a mounting portion, a printed circuit board (PCB) disposed on the bracket, a heat generating component disposed on a surface of the PCB facing the bracket, a battery spaced apart from the heat generating component and accommodated in the bracket, a vapor chamber on the mounting portion of the bracket. The vapor chamber may include a first portion disposed above the heat generating component, a second portion interposed between the mounting portion and the battery, and a third portion extending from the first portion to the second portion.

An electronic device is disclosed. The electronic device may include a bracket including a mounting portion, a printed circuit board (PCB) overlapping with the bracket, a heat generating component on a surface of the PCB, the surface facing the bracket, a shield can on the surface of the PCB and surrounding the heat generating component, the shield can including a through hole, a shielding sheet connected to the shield can to cover the through hole of the shield can, a heat conduction member in the through hole and between the heat generating component and the shielding sheet, a battery spaced apart from the heat generating component and accommodated in the bracket, and a vapor chamber on mounting portion of the bracket. The vapor chamber may include a first portion above the shielding sheet, a second portion between the mounting portion and the battery, and a third portion extending from the first portion to the second portion.

### BRIEF DESCRIPTION OF DRAWINGS

FIG. 1 is a block diagram of an electronic device in a network environment according to various embodiments.

FIG. 2A illustrates an unfolded state of an example electronic device.

FIG. 2B illustrates a folded state of an example electronic device.

FIG. 2C is an exploded view of an example electronic device.

FIG. 3A illustrates an unfolded state of an example electronic device.

FIG. 3B illustrates a folded state of an example electronic device.

FIG. 4 illustrates a portion of an example electronic device.

FIG. 5A illustrates a portion of an example electronic device.

FIG. 5B is a partially exploded perspective view of an example electronic device.

FIG. 5C illustrates a portion of an example electronic device.

FIGS. 6A and 6B illustrate a portion of an example electronic device.

FIGS. 6C, 6D, and 6E illustrate a vapor chamber of an example electronic device.

FIG. 7A is a cross-sectional view of a vapor chamber of an example electronic device cut along a line A-A′ of FIG. 6A.

FIG. 7B is a top plan view of a first plate of a vapor chamber of an example electronic device.

FIG. 7C is a top plan view of a second plate of a vapor chamber of an example electronic device.

FIG. 7D illustrates a portion of a second plate of a vapor chamber of an example electronic device.

FIG. 8 illustrates a structure for heat dissipation of an example electronic device.

FIG. 9A is a diagram illustrating an example electronic device.

FIG. 9B is an exploded perspective view of an example electronic device.

### DETAILED DESCRIPTION

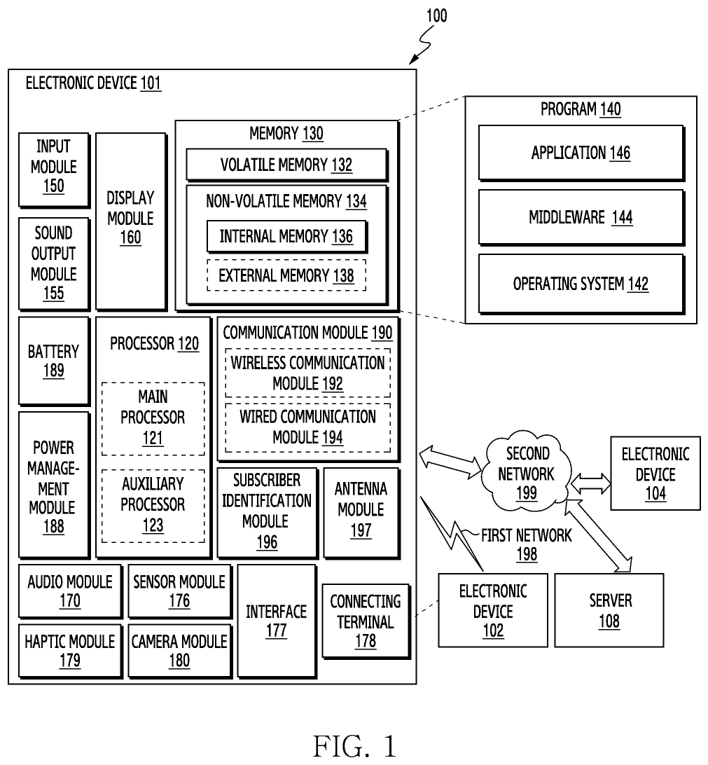

FIG. 1 is a block diagram of an electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but the disclosure is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may change a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may change an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mm Wave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mm Wave band), and a plurality of antennas (e.g., array antennas) disposed on a second surface (e.g., the top or a side exterior surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices (e.g., the electronic device 102, the electronic device 104, or the server 108). For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra-low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

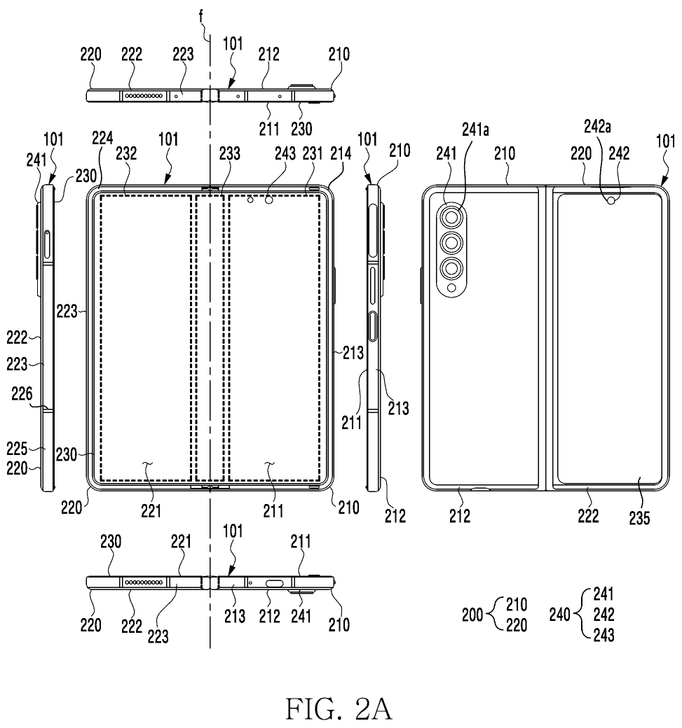

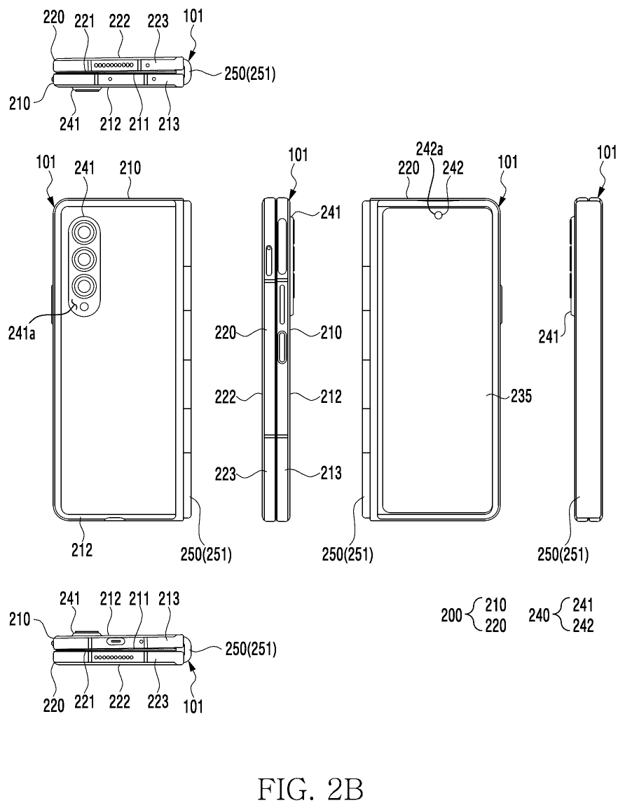

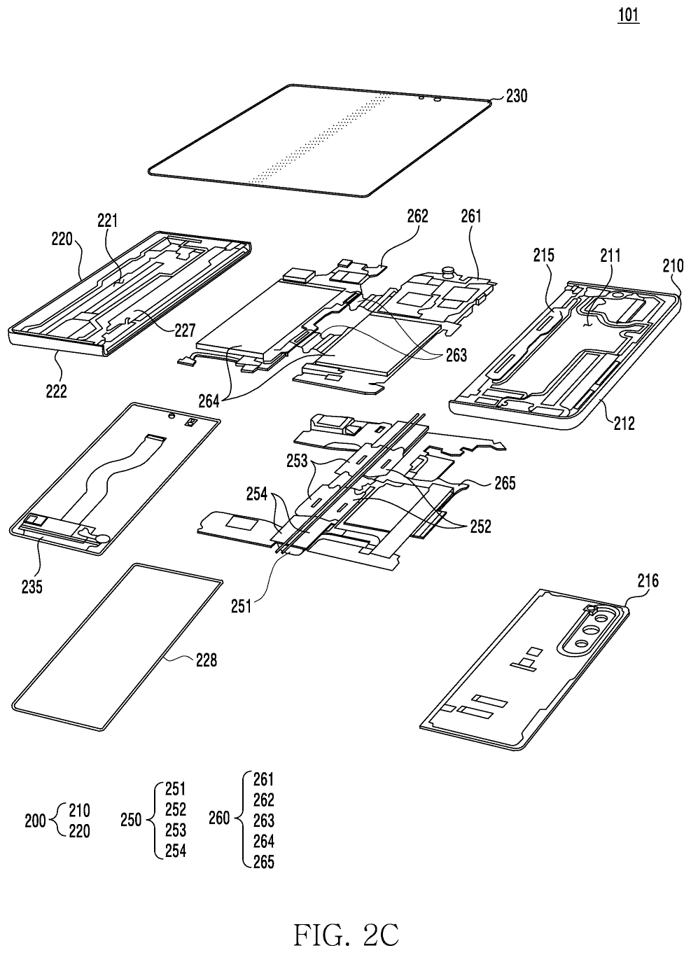

FIG. 2A illustrates an unfolded state of an example electronic device. FIG. 2B illustrates a folded state of an example electronic device. FIG. 2C is an exploded view of an example electronic device.

Referring to FIGS. 2A, 2B, and 2C, the electronic device 101 may include a housing 200 including a first housing part 210 and a second housing part 220, a display 230, at least one camera 240 (e.g., the camera module 180 of FIG. 1), a hinge structure 250, and/or at least one electronic component 260.

The first housing part 210 and the second housing part 220 may form at least a part of an outer surface of the electronic device 101 that may be gripped by a user. The at least the part of the outer surface of the electronic device 101 defined by the first housing part 210 and the second housing part 220 may come into contact with a part of a user's body, when the electronic device 101 is used by the user. According to an embodiment, the first housing part 210 may include a first front surface 211, a first rear surface 212 facing the first front surface 211 and spaced apart from the first front surface 211, and first side surfaces 213 surrounding at least a part of the first front surface 211 and the first rear surface 212. The first side surfaces 213 may connect a periphery of the first front surface 211 to a periphery of the first rear surface 212. The first front surface 211, the first rear surface 212, and the first side surfaces 213 may define an inner space of the first housing part 210. According to an embodiment, the first housing part 210 may provide the space formed by the first front surface 211, the first rear surface 212, and the first side surfaces 213 as a space for arranging components of the electronic device 101.

The second housing part 220 may include a second front surface 221, a second rear surface 222 facing away from the second front surface 221 and spaced apart from the second front surface 221, and second side surfaces 223 surrounding at least a portion of the second front surface 221 and the second rear surface 222. The second side surfaces 223 may connect a periphery of the second front surface 221 and a periphery of the second rear surface 222. The second front surface 221, the second rear surface 222, and the second side surfaces 223 may define an inner space of the second housing part 220. According to an embodiment, the second housing part 220 may provide the space formed by the second front surface 221, the second rear surface 222, and the second side surfaces 223 surrounding at least a portion of the second front surface 221 and the second rear surface 222, as a space for mounting components of the electronic device 101. According to an embodiment, the second housing part 220 may be coupled to the first housing part 210 to be rotatable relative to the first housing part 210.

Each of the first housing part 210 and the second housing part 220 may include each of a first protective member 214 and a second protective member 224. The first protective member 214 and the second protective member 224 may be disposed on the first front surface 211 and the second front surface 221 along a periphery of the display 230. According to an embodiment, the first protective member 214 and the second protective member 224 may prevent an inflow of foreign matter (e.g., dust or moisture) through a gap between the display 230, the first housing part 210, and the second housing part 220. For example, the first protective member 214 may surround a periphery of a first planar portion 231 of the display 230, and the second protective member 224 may surround a periphery of a second planar portion 232 of the display 230. The first protective member 214 may be formed attached to the first side surfaces 213 of the first housing part 210 or may be formed integrally with the first side surfaces 213. The second protective member 224 may be formed attached to the second side surfaces 223 of the second housing part 220, or may be formed integrally with the second side surfaces 223.

The first side surfaces 213 and the second side surfaces 223 may include a conductive material, a non-conductive material, or a combination thereof. For example, the second side surfaces 223 may include at least one conductive portion 225 and at least one non-conductive portion 226. The at least one conductive portion 225 may include a plurality of conductive portions spaced apart from each other. The at least one non-conductive portion 226 may be disposed between a plurality of conductive portions. The plurality of conductive portions may be disconnected (e.g., electrically insulated) from each other by at least one non-conductive portion 226 disposed between the plurality of conductive portions. According to an embodiment, a plurality of conductive portions and a plurality of non-conductive portions may form an antenna radiator altogether. The electronic device 101 may communicate with an external electronic device via the antenna radiator formed by a plurality of conductive portions and a plurality of non-conductive portions.

The display 230 may be configured to display visual information. According to an embodiment, the display 230 may be disposed on the first front surface 211 of the first housing part 210 and the second front surface 221 of the second housing part 220 across the hinge structure 250. For example, the display 230 may include a first planar portion 231 disposed on the first front surface 211 of the first housing, a second planar portion 232 disposed on the second front surface 221 of the second housing, and a foldable portion 233 disposed between the first planar portion 231 and the second planar portion 232. The first planar portion 231, the second planar portion 232, and the foldable portion 233 may form an entire front surface of the display 230. According to an embodiment, the display 230 may further include a sub-display 235 disposed on the second rear surface 222 of the second housing part 220. For example, the display 230 may be referred to as a flexible display. According to an embodiment, the display 230 may include a window exposed toward the outside of the electronic device 101. The window may be configured to protect the surface of the display 230 and include a substantially transparent material, so as to transmit visual information provided by the display 230 to the outside of the electronic device 101. For example, the window may include glass (e.g., ultra-thin glass (UTG)) and/or polymer (e.g., polyimide (PI)), but the present disclosure is not limited thereto.

At least one camera 240 may be configured to obtain an image based on receiving light from a subject outside the electronic device 101. According to an embodiment, the at least one camera 240 may include first cameras 241, a second camera 242, and/or a third camera 243. The first cameras 241 may be disposed in the first housing part 210. For example, the first cameras 241 may be disposed inside the first housing part 210, and at least a portion of the first cameras 241 may be visible through the first rear surface 212 of the first housing part 210. The first cameras 241 may be supported by a bracket (not shown) in the first housing part 210. The first housing part 210 may include at least one opening 241a overlapping with the first cameras 241, when viewed from above. The first cameras 241 may obtain an image based on receiving light from the outside of the electronic device 101 through the at least one opening 241a.

The second camera 242 may be disposed within the second housing part 220. For example, the second camera 242 may be disposed inside the second housing part 220 and may be visible through the sub-display 235. The second housing part 220 may include at least one opening 242a overlapping with the second camera 242, when viewed from above. The second camera 242 may obtain an image based on receiving light from the outside of the electronic device 101 through the at least one opening 242a.

The third camera 243 may be disposed in the first housing part 210. For example, the third camera 243 may be disposed inside the first housing part 210, and at least a portion thereof may be visible through the first front surface 211 of the first housing part 210. As another example, the third camera 243 may be disposed inside the first housing part 210, and at least a portion thereof may be visible through the first planar portion 231 of the display 230. The first planar portion 231 of the display 230 may include at least one opening (not shown) overlapping with the third camera 243, when viewed from above. The third camera 243 may obtain an image based on receiving light from the outside of the display 230 through the at least one opening.

The second camera 242 and the third camera 243 may be disposed under the display 230 (e.g., in a direction toward the inside of the first housing part 210 or the inside of the second housing part 220). For example, the second camera 242 and the third camera 243 may be an under display camera (UDC). When the second camera 242 and the third camera 243 are under display cameras, one area of the display 230 corresponding to the position of each of the second camera 242 and the third camera 243 may not be an inactive area. When the second camera 242 and the third camera 243 are under display cameras, one area of the display 230 corresponding to the position of each of the second camera 242 and the third camera 243 may have a pixel density lower than a pixel density of other areas of the display 230. The inactive area of the display 230 may refer to an area of the display 230 that does not have pixels or does not emit light to the outside of the electronic device 101. As another example, the second camera 242 and the third camera 243 may be punch hole cameras. When the second camera 242 and the third camera 243 are punch hole cameras, one area of the display 230 corresponding to the position of each of the second camera 242 and the third camera 243 may be an inactive area. When the second camera 242 and the third camera 243 are punch hole cameras, one area of the display 230 corresponding to the position of each of the second camera 242 and the third camera 243 may include an opening that does not have any pixels.

The hinge structure 250 may rotatably connect the first housing part 210 and the second housing part 220. The hinge structure 250 may be disposed between the first housing part 210 and the second housing part 220 of the electronic device 101 so that the electronic device 101 may be bent, bending, or folded. For example, the hinge structure 250 may be disposed between a part of the first side surfaces 213 and a part of the second side surfaces 223 facing each other. The hinge structure 250 may change the electronic device 101 to an unfolding state in which the facing directions the first front surface 211 of the first housing part 210 and the second front surface 221 of the second housing part 220 face are substantially the same as each other, or a folding state in which the first front surface 211 and the second front surface 221 face each other. When the electronic device 101 is in a folded state, the first housing part 210 and the second housing part 220 may face each other to lie one upon another or overlap each other.

When the electronic device 101 is in a folded state, the direction in which the first front surface 211 faces may be different from the direction in which the second front surface 221 faces. For example, when the electronic device 101 is in the folded state, the direction in which the first front surface 211 faces may be opposite to the direction in which the second front surface 221 faces. For another example, when the electronic device 101 is in the folded state, the direction in which the first front surface 211 faces and the direction in which the second front surface 221 faces may be inclined with respect to each other. When the direction in which the first front surface 211 faces is inclined with respect to the direction in which the second front surface 221 faces, the first housing part 210 may be inclined with respect to the second housing part 220. However, the present disclosure is not limited thereto. For example, in the folded state of the electronic device 101, the first rear surface 212 of the first housing part 210 may face the second rear surface 222 of the second housing part 220. When the first rear surface 212 and the second rear surface 222 face each other in the folded state of the electronic device 101, the direction in which the first front surface 211 faces and the direction in which the second front surface 221 faces may be opposite to each other. When the first rear surface 212 and the second rear surface 222 face each other in the folded state of the electronic device 101, the display 230 may be directly exposed to the outside in the folded state of the electronic device 101.

The electronic device 101 may be foldable with respect to a folding axis f. The folding axis f may refer to a virtual line extending through a hinge cover 251 in a direction substantially parallel to a lengthwise direction of the electronic device 101, but the present disclosure is not limited thereto. For example, the folding axis f may be a virtual line extending in a direction substantially perpendicular to the lengthwise direction of the electronic device 101. When the folding axis f extends in the direction substantially perpendicular to the lengthwise direction of the electronic device 101, the hinge structure 250 may extend in a direction side by side to the folding axis f to connect the first housing part 210 and the second housing part 220. The first housing part 210 and the second housing part 220 may be rotatable by the hinge structure 250 extending in the direction substantially perpendicular to the lengthwise direction of the electronic device 101.

The hinge structure 250 may include the hinge cover 251, a first hinge plate 252, a second hinge plate 253, and a hinge module 254. The hinge cover 251 may surround internal components of the hinge structure 250 and form an outer surface of the hinge structure 250. According to an embodiment, when the electronic device 101 is in the folded state, at least a portion of the hinge cover 251 surrounding the internal components of the hinge structure 250 may be exposed to the outside of the electronic device 101 through a space between the first housing part 210 and the second housing part 220. According to an embodiment, when the electronic device 101 is in the unfolded state, the hinge cover 251 may be covered by the first housing part 210 and the second housing part 220 and may not be exposed to the outside of the electronic device 101.

The first hinge plate 252 and the second hinge plate 253 may be coupled to the first housing part 210 and the second housing part 220, respectively, and thus may rotatably connect the first housing part 210 and the second housing part 220. For example, the first hinge plate 252 may be coupled to a first bracket 215 of the first housing part 210, and the second hinge plate 253 may be coupled to a second bracket 227 of the second housing part 220. As the first hinge plate 252 and the second hinge plate 253 are coupled to the first bracket 215 and the second bracket 227, respectively, the first housing part 210 and the second housing part 220 may be rotatable according to the rotation of the first hinge plate 252 and the second hinge plate 253.

The hinge module 254 may rotate the first hinge plate 252 and the second hinge plate 253. The hinge module 254 may include gears that may be engaged to rotate, thereby rotating the first hinge plate 252 and the second hinge plate 253 with respect to the folding axis f. According to an embodiment, there may be arranged a plurality of hinge modules 254. For example, the plurality of hinge modules 254 may be disposed to be spaced apart from each other at both ends of the first hinge plate 252 and the second hinge plate 253, respectively.

The first housing part 210 may include the first bracket 215 and a first cover 216, and the second housing part 220 may include the second bracket 227 and a second cover 228. The first bracket 215 and the first cover 216 may be configured to support components of the electronic device 101. The first bracket 215 may be coupled to the first cover 216 to define the first housing part 210. The first cover 216 may define a part of an outer surface of the first housing part 210. The second bracket 227 and the second cover 228 may be configured to support components of the electronic device 101. The second bracket 227 may be coupled to the second cover 228 to define the second housing part 220. The second cover 228 may define a part of the outer surface of the second housing part 220. For example, the display 230 may be disposed on one surface of the first bracket 215 and one surface of the second bracket 227. The first cover 216 may be disposed on the other surface of the first bracket 215 opposite to one surface of the first bracket 215. The second cover 228 may be disposed on the other surface of the second bracket 227 opposite to one surface of the second bracket 227. The sub-display 235 may be disposed between the second bracket 227 and the second cover 228.

A part of the first bracket 215 may be surrounded by the first side surfaces 213 and a part of the second bracket 227 may be surrounded by the second side surfaces 223. For example, the first bracket 215 may be integrally formed with the first side surfaces 213, and the second bracket 227 may be integrally formed with the second side surfaces 223. For another example, the first bracket 215 may be formed separately from the first side surfaces 213, and the second bracket 227 may be formed separately from the second side surfaces 223.

At least one electronic component 260 may implement various functions to be provided to a user. According to an embodiment, the at least one electronic component 260 may include a first printed circuit board 261, a second printed circuit board 262, a flexible printed circuit board 263, a battery 264 (e.g., the battery 189 of FIG. 1), and/or an antenna 265 (e.g., the antenna module 197 of FIG. 1). The first printed circuit board 261 and the second printed circuit board 262 may form an electrical connection between components in the electronic device 101. For example, the components (e.g., the processor 120 of FIG. 1) for implementing the overall function of the electronic device 101 may be disposed on the first printed circuit board 261, and at least one electronic component for implementing some functions of the first printed circuit board 261 may be disposed on the second printed circuit board 262. As another example, components for operating the sub-display 235 disposed on the second rear surface 222 may be arranged on the second printed circuit board 262.

The first printed circuit board 261 may be disposed in the first housing part 210. For example, the first printed circuit board 261 may be disposed on one surface of the first bracket 215. According to an embodiment, the second printed circuit board 262 may be disposed within the second housing part 220. For example, the second printed circuit board 262 may be spaced apart from the first printed circuit board 261 and may be disposed on one surface of the second bracket 227. The flexible printed circuit board 263 may connect the first printed circuit board 261 and the second printed circuit board 262. The flexible printed circuit board 263 may extend from the first printed circuit board 261 to the second printed circuit board 262.

The battery 264 may be a device for supplying power to at least one component of the electronic device 101, and may include, for example, a non-rechargeable primary battery, a rechargeable secondary battery, and/or a fuel cell. At least a portion of the battery 264 may be disposed on substantially the same plane as the first printed circuit board 261 or the second printed circuit board 262.

The antenna 265 may be configured to receive power or signals from the outside of the electronic device 101. According to an embodiment, the antenna 265 may be disposed between the first cover 216 and the battery 264. The antenna 265 may include, for example, a near field communication (NFC) antenna, an antenna module, and/or a magnetic secure transmission (MST) antenna. The antenna 265 may, for example, perform short-range communication with an external device, and/or wirelessly transmit and receive electrical power required for charging.

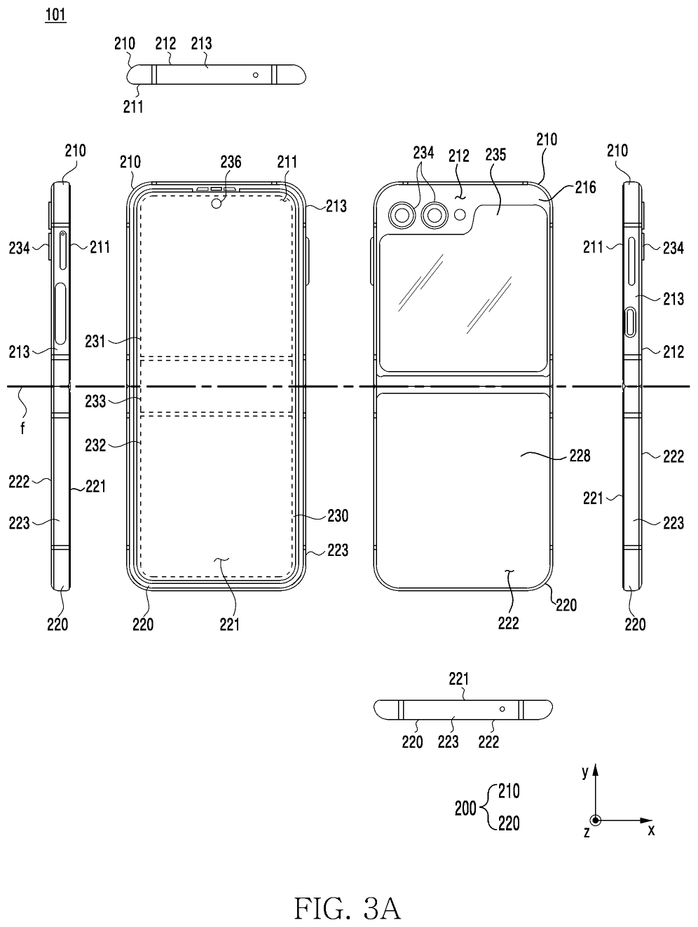

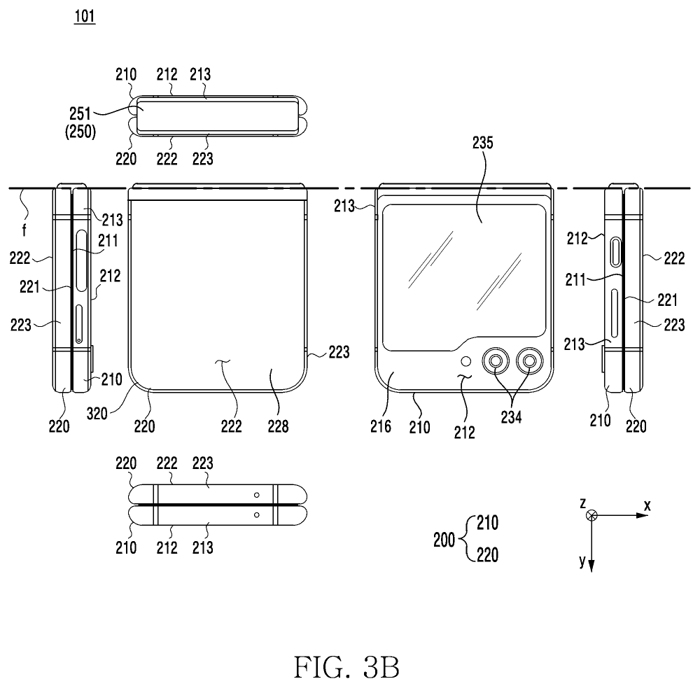

FIG. 3A illustrates an unfolded state of an example electronic device. FIG. 3B illustrates a folded state of an example electronic device.

An electronic device 101 illustrated and described as an example in FIGS. 3A and 3B may have a housing 200 including a first housing 210 and a second housing 220 rotatable with respect to the first housing 210, like the electronic device 101 illustrated and described in FIGS. 2A to 2C. The electronic device 101 illustrated and described as an example in FIGS. 3A and 3B may be referred to as a foldable electronic device, in terms of including a display 230 having a foldable portion 233 that is deformable by a hinge structure 250 (or a hinge assembly) configured to rotate the second housing 220 with respect to the first housing 210, like the electronic device 101 illustrated and described with reference to FIGS. 2A to 2C. For example, the folding axis f of the electronic device 101 illustrated and described in FIGS. 3A and 3B may be parallel to the x-axis, as illustrated. Unlike the electronic device 101 illustrated and described in FIGS. 3A to 3C, the folding axis f of the electronic device 101 illustrated and described in FIGS. 2A and 2B may be parallel to the y-axis orthogonal to the x-axis. However, the electronic device 101 illustrated and described in FIGS. 2A to 3B is a non-limiting example, and the electronic device 101 may have various foldable form factors (e.g., a multi-foldable electronic device capable of being folded multiple times). Hereinafter, the electronic device 101 illustrated in FIGS. 3A and 3B will be described with reference to the description of components having the same reference numerals as those of FIGS. 2A to 2C.

The electronic device 101 may include the housing 200 including the first housing 210 and the second housing 220, and the hinge structure (or a hinge assembly) 250. The first housing 210 may be rotatably connected to the hinge structure 250. The first housing 210 may be rotated with respect to the second housing 220 using the hinge structure 250. The second housing 220 may be rotatably connected to the hinge structure 250. The second housing 220 may be rotated with respect to the first housing 210 with the hinge structure 250.

The first housing 210 may include a first front surface 211, a first rear surface 212 faced away the first front surface 211, and first side surfaces 213 surrounding at least a portion of the first front surface 211 and the first rear surface 212. The first housing 210 may provide a space for disposing components of the electronic device 101. The first housing 210 may include a conductive material, a non-conductive material, or a combination thereof.

The second housing 220 may include a second front surface 221, a second rear surface 222 facing away the second front surface 221, and second side surfaces 223 surrounding at least a portion of the second front surface 221 and the second rear surface 222. The second housing 220 may provide a space for disposing the components of the electronic device 101.

The hinge structure 250 may be connected to each of the first housing 210 and the second housing 220. For example, the hinge structure 250 may include a first hinge plate (e.g., the first hinge plate 252 of FIG. 2C) and a second hinge plate (e.g., the second hinge plate 253 of FIG. 2C), which are rotatably configured. The first hinge plate may be connected to the first housing 210, and the first housing 210 may be rotated by the first hinge plate. The second hinge plate may be connected to the second housing 220, and the second housing 220 may be rotated by the second hinge plate.

The electronic device 101 may be folded or unfolded with respect to the folding axis f passing through the hinge structure 250 according to the rotation of the first housing 210 and the second housing 220. The hinge structure 250 may be positioned between the first housing 210 and the second housing 220 so that the electronic device 101 may be folded with respect to the folding axis f.

The hinge structure 250 may include a hinge cover 251 to cover an internal structure making up a mechanism of the hinge structure. The hinge cover 251 may be exposed to the outside depending on the extent of folding of the electronic device 101, or may be covered by the first housing 210 and the second housing 220. For example, while the electronic device 101 is in an folded state (e.g., FIG. 3B), the hinge cover 251 may be at least partially exposed through between the first housing 210 and the second housing 220. For example, while the electronic device 101 is in the unfolded state (e.g., FIG. 3A), the hinge cover 251 may be covered by the first housing 210 and the second housing 220.

The electronic device 101 may include a display 230 (e.g., the display module 160 of FIG. 1) disposed within the space formed by the first housing 210 and the second housing 220. For example, the display 230 may be at least partially accommodated in recesses formed in the first front surface 211 of the first housing 210 and the second front surface 221 of the second housing 220. The display 230 may include a first planar portion 231 aligned with respect to the first housing 210, a second planar portion 232 spaced apart from the first planar portion 231 and aligned with the second housing 220, and a foldable portion 233 aligned with respect to the hinge structure 250 and extending from the first planar portion 231 to the second planar portion 232. The display 230 may be referred to as a foldable display or a flexible display. The first planar portion 231, the second planar portion 232, and the foldable portion 233 may form a surface of the display 230. The surface of the display 230 may at least partially form the first front surface 211 of the first housing 210 and the second front surface 221 of the second housing 220. The first planar portion 231, the second planar portion 232, and the foldable portion 233 may respectively define a first display area, a second display area, and a third display area of the display 230 on which visual information may be displayed.

The electronic device 101 may include a sub-display 235 (e.g., the display module 160 of FIG. 1) disposed within the first housing 210. The sub-display 235 may be viewed through the second rear surface 222 of the first housing 210.

The electronic device 101 may include a plurality of cameras (e.g., the camera module 180 of FIG. 1). For example, the electronic device 101 may include cameras 234 and 236. The camera 234 may be disposed inside the first housing 210 to obtain an image through a part of the first rear surface 212. The camera 236 may be disposed under the first planar portion 231 of the display 230. The camera 236 may be aligned with an opening at least partially passing through the first planar portion 231, and may obtain an image through the hole. The camera 236 may be located in a screen display area of the display 230, but the present disclosure is not limited thereto.

Hereinafter, the states of the electronic device 101 will be described. The electronic device 101 may include a plurality of states including an unfolded state (e.g., FIG. 3A) and a folded state (e.g., FIG. 3B). The electronic device 101 may be transformed or change in between the unfolded state and the folded state. Further, the electronic device 101 may include a plurality of intermediate states between the unfolded state and the folded state. The angle between the first housing 210 and the second housing 220 may vary depending on the state of the electronic device 101.

Referring to FIG. 3A, in the unfolded state, the first housing 210 and the second housing 220 may form a first angle. For example, the first angle may be about 180 degrees. The first planar portion 231, the second planar portion 232, and the foldable portion 233 of the display 230 may form a substantially flat surface. A direction (e.g., +z direction) in which the first front surface 211 (or the first planar portion 231) of the first housing 210 faces may be substantially the same as a direction (e.g., +z direction) in which the second front surface 221 (or the second planar portion 232) of the second housing 220 faces.

Referring to FIG. 3B, in the unfolded state of the electronic device 101, the first housing 210 and the second housing 220 may be folded to face each other by rotating with respect to the folding axis f. The first housing 210 and the second housing 220 may be overlapped with each other to form a second angle less than the first angle. The second angle may be about 0°. The foldable portion 233 of the display 230 may be bent to correspond to the second angle. The first front surface 211 of the first housing 210 may face the second front surface 221 of the second housing 220 or may overlap the second front surface 221. The first housing 210 and the second housing 220 may at least partially contact each other, but the present disclosure is not limited thereto. A direction (e.g., +z direction) toward which the first front surface 211 of the first housing 210 faces may be opposite to a direction (e.g., −z direction) toward with the second front surface 221 of the second housing 220. In the folded state, at least a portion of the display 230 may not be visible from the outside of the electronic device 101, and the sub-display 235 may be visible from the outside the electronic device 101.

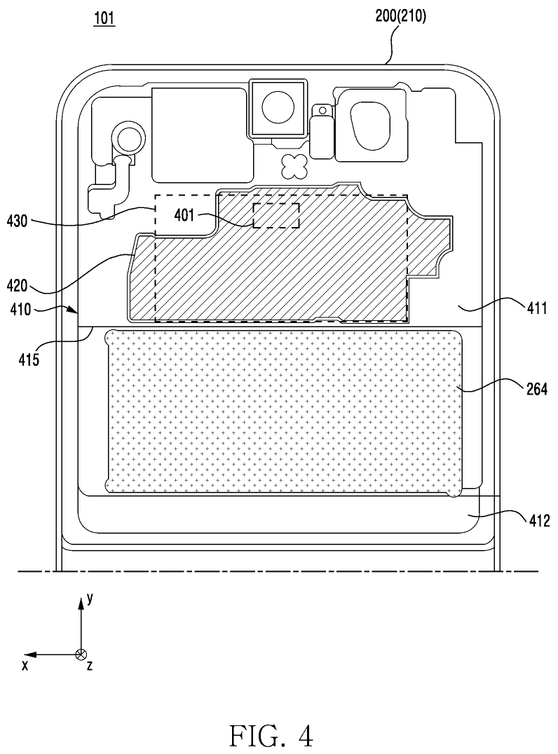

FIG. 4 illustrates a portion of an example electronic device.

Referring to FIG. 4, the electronic device 101 may include a housing 200 including a bracket 410 (e.g., the first bracket 215 of FIG. 2C), a heat dissipation sheet 420, a printed circuit board 430, and a battery 264. The housing 200 may be the first housing part 210 amongst the first housing part 210 and the second housing part 220 of the electronic device 101 illustrated and described in FIGS. 2A to 3B, but embodiment of the present disclosure are not limited thereto.

The bracket 410 may support the display 230 of the electronic device 101 and/or structures disposed underneath the display 230 to support the display 230. For example, the bracket 410 may form at least a part of the exterior of the housing 200. For example, the bracket 410 may provide a space for accommodating electronic components within the electronic device 101. At least some of the electronic components may be electrically connected to the display 230. However, embodiments of the present disclosure are not limited thereto.

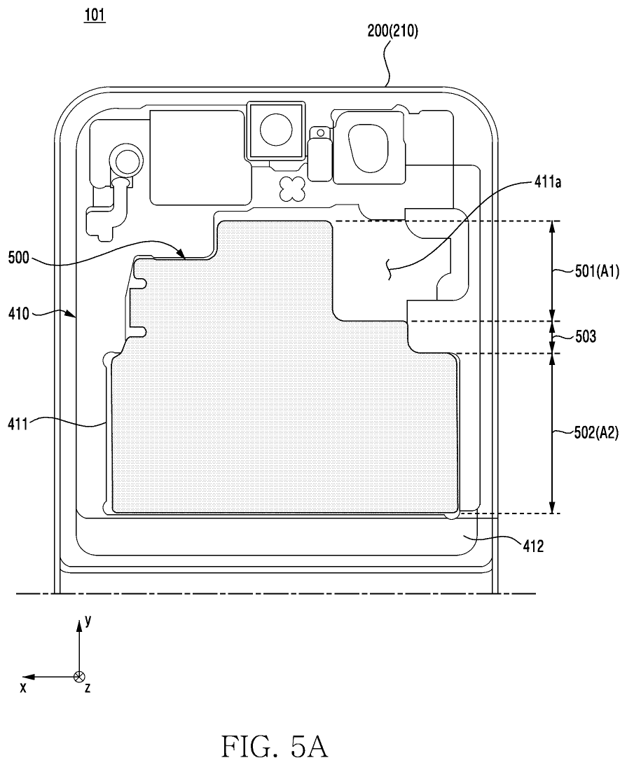

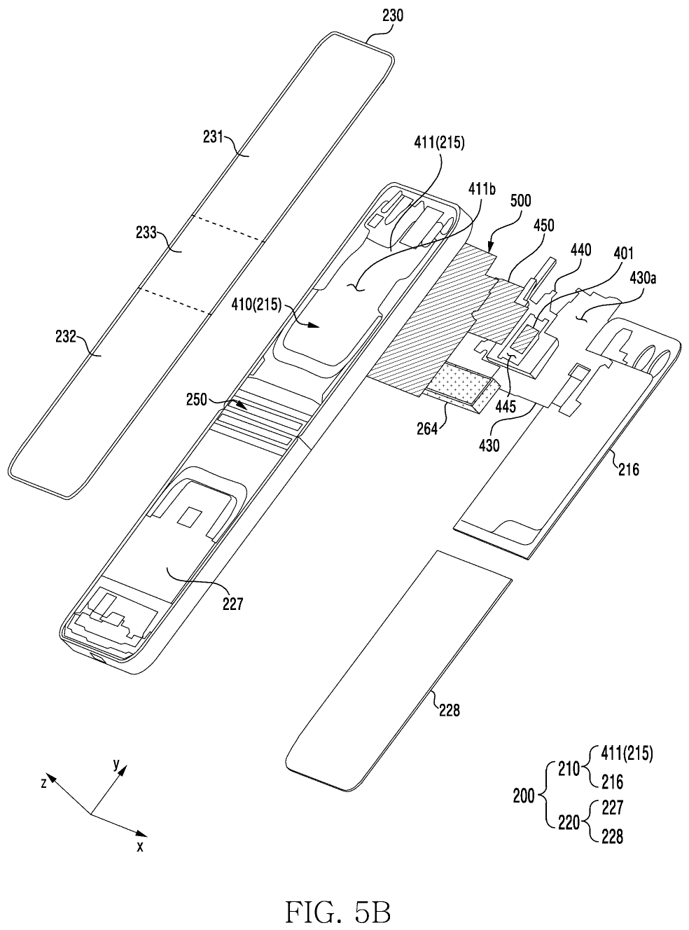

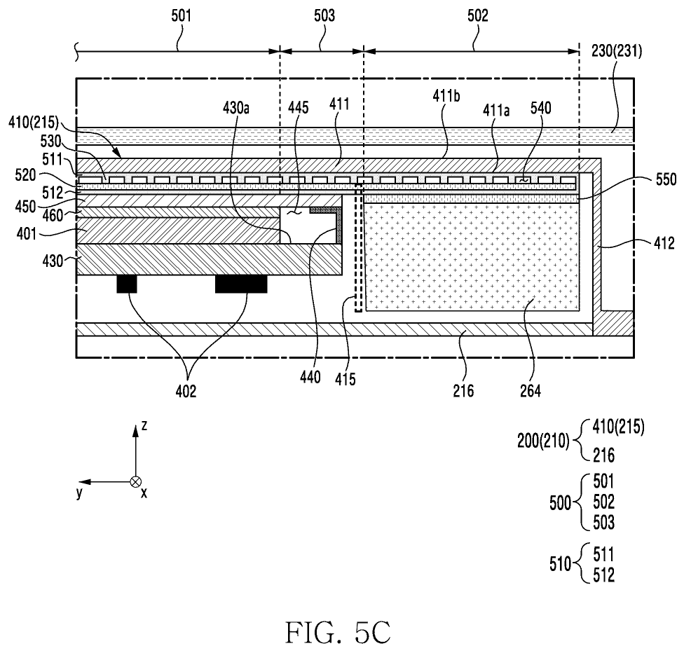

The bracket 410 may include a mounting portion 411. The mounting portion 411 may be disposed under the display 230 of the electronic device 101. For example, the mounting portion 411 may face at least a portion of the display 230. For example, at least some of the electronic components of the electronic device 101 may be mounted or disposed onto the mounting portion 411. For example, the mounting portion 411 may define one surface (e.g., a second surface 411b of FIG. 5B) facing the display 230 and another surface (e.g., a first surface 411a of FIG. 5A) opposite to the one surface. For example, some of the electronic components of the electronic device 101 having a relatively large dimensions (e.g., the battery 264, the printed circuit board 430 of FIG. 5B) may be disposed on the other surface of the mounting portion 411 for the display 230. For example, the mounting portion 411 may be surrounded by a peripheral portion (or side bezel structure) of the housing 200. The mounting portion 411 and the peripheral part may be formed of different materials, but embodiments of the present disclosure are not limited thereto.

The bracket 410 may include a sidewall 412. For example, the sidewall 412 may protrude from the mounting portion 411 to form a space for accommodating electronic components within the housing 200 together with the mounting portion 411. For example, the sidewall 412 may protrude from one surface (e.g., the second surface 411b of FIG. 5B) facing the display 230 of the mounting portion 411 and the other surface (e.g., the first surface 411a of FIG. 5A) opposite to the one surface, thereby coming into contact with or being coupled to the rear cover of the housing 200 (e.g., the first cover 216 of FIG. 2C) facing the other surface. However, embodiments of the present disclosure are not limited thereto.

The battery 264 may be seated onto the mounting portion 411 of the bracket 410. The battery 264 may be supported by the mounting portion 411 and/or the sidewall 412 of the bracket 410. The battery 264 may be disposed in an inner space of the housing 200 formed by the mounting portion 411 of the bracket 410 and the sidewall 412. For example, as the battery 264 may have a relatively large volume, it may be attached onto one surface (e.g., the second surface 411b of FIG. 5B) facing the display 230 of the mounting portion 411 and the other surface (e.g., the first surface 411a of FIG. 5A) opposite to the one surface. For example, the battery 264 may be configured to be rechargeable for driving the electronic device 101 and/or the electronic components in the electronic device 101. However, embodiments of the present disclosure are not limited thereto.

The printed circuit board 430 may be disposed on the bracket 410 (or the mounting portion 411). Electronic components for driving and/or executing functions of the electronic device 101 may be coupled to the printed circuit board 430. For example, the printed circuit board 430 may be accommodated in the bracket 410 together with the battery 264. For example, the printed circuit board 430 may be connected to the battery 264 to supply power to the electronic device 101 and/or electronic components inside the electronic device 101 from the battery 264. For example, a power management integrated circuit (PMIC) in the printed circuit board 430 may be connected to the battery 264 via a flexible printed circuit board (FPCB) to supply power to the electronic device 101. For example, the printed circuit board 430 may be disposed adjacent to the battery 264 for connecting with the battery 264. The printed circuit board 430 may be disposed, for example, on one surface (e.g., the first surface 411a of FIG. 5B) of the mounting portion 411 of the bracket 410 together with the battery 264. For example, the printed circuit board 430 may be disposed along the battery 264 or next to the battery 264. For example, the printed circuit board 430 may be disposed in a space surrounded by the mounting portion 411 of the bracket 410, the sidewall 412 of the bracket 410, and the rear cover of the housing 200 (e.g., the first cover 216 of FIG. 2A). However, embodiments of the present disclosure are not limited thereto.

The bracket 410 may include a partition wall 415. The partition wall 415 may, for example, protrude from the mounting portion 411 to partition a space for accommodating electronic components together with the sidewall 412 of the bracket 410. The partition wall 415 may, for example, protrude from one surface facing the display 230 of the mounting portion 411 (e.g., the second surface 411b of FIG. 5B) and the other surface opposite to the one surface (e.g., the first surface 411a of FIG. 5A) toward the rear cover of the housing 200 (e.g., the first cover 216 of FIG. 2C) facing the other surface. For example, the partition wall 415 may come into contact with the battery 264 to support the battery 264. By supporting the battery 264, the partition wall 415 may reduce movement or dislodgement of the battery 264 from the mounting portion 411 due to any external impact. For example, the partition wall 415 may be at least partially disposed between the battery 264 and the printed circuit board 430. The battery may be isolated or separated from the printed circuit board above 430 by the partition wall 415. However, embodiments of the present disclosure are not limited thereto.

An electronic component 401 may be disposed on the printed circuit board 430 and may emit heat while the electronic device 101 is in operation. For example, the electronic component 401 may be a processor (e.g., the processor 120 of FIG. 1) of the electronic device 101 having a relatively large amount of heat generation. For example, the electronic component 401 may be coupled on one surface (e.g., the one surface 430a of FIG. 5B) facing the mounting portion 411 of the printed circuit board 430. For example, the electronic component 401 may perform data processing or arithmetic operation according to the operation of the electronic device 101. For example, the electronic component 401 may dissipate heat to the surroundings of the electronic component 401 while performing data processing or calculation. The electronic component 401 may be referred to as a heat generating component or a heat generating body in that it is a heat generating element, but embodiments of the present disclosure are not limited thereto. The electronic device 101 may include a heat dissipation structure to reduce possible damage to the electronic component 401 and/or one or more other electronic components around the electronic component 401 due to the heat emitted from the electronic component 401.

The heat dissipation sheet 420 may be attached to the mounting portion 411 of the bracket 410. The heat dissipation sheet 420 may be disposed toward the printed circuit board 430 and/or the electronic component 401 disposed on the printed circuit board 430. For example, the heat dissipation sheet 420 may at least partially overlap the electronic component 401 and/or the printed circuit board 430, when the mounting portion 411 is viewed from above (e.g., viewed in +z direction). For example, the heat dissipation sheet 420 may be disposed above the electronic component 401. Throughout the present disclosure, when references are made to a positional relationship between an element and another element (e.g., “on,” “above or over,” “below or beneath,” “under,” “next to”), unless expressions such as “rightly” or “directly” are used, it is to be understood that one or more intervening elements may exist between the two elements, and that it is not intended to limit the placement relationship between the two elements thereto. For example, an expression “the heat dissipation sheet 420 disposed above the electronic component 401” may imply “the heat dissipation sheet 420 disposed over the electronic component 401” in the +z direction. For example, an expression “the heat dissipation sheet 420 disposed above the electronic component 401” may imply “the heat dissipation sheet 420 disposed under the electronic component 401” in the −z direction. For example, an expression “the heat dissipation sheet 420 disposed above the electronic component 401” may imply “the heat dissipation sheet 420 facing the electronic component 401 and spaced apart from the electronic component 401.” However, embodiments of the present disclosure are not limited thereto.

For example, since the heat dissipation sheet 420 is disposed toward the electronic component 401, at least part of the heat emitted from the electronic component 401 may be transferred thereto. The heat dissipation sheet 420 may distribute the heat received from the electronic component 401, thereby reducing damage to the electronic component 401 and/or one or more other electronic components around the electronic component 401 due to the heat. The heat dissipation sheet 420 may include a material (e.g., graphite) having relatively high thermal conductivity, but embodiments of the present disclosure are not limited thereto.

The size (or area) for heat dissipation of the electronic component 401 of the heat dissipation sheet 420 may be limited by the partition wall 415 of the bracket 410 for supporting the battery 264. For example, the heat dissipation sheet 420 may be isolated from or separated from the battery 264 by the partition wall 415. As a portion of the mounting portion 411 to which the heat dissipation sheet 420 may be attached is limited by the partition wall 415, the performance of an electronic device for heat dissipation of the electronic component 401 may deteriorate in a comparative embodiment. Referring to illustration of FIG. 5A, description will be made of a vapor chamber 500 of the electronic device 101 for heat dissipation of the electronic component 401 and the internal structure of the electronic device 101 for arranging the vapor chamber 500.

FIG. 5A illustrates a portion of an example electronic device. FIG. 5B is a partially exploded perspective view of an example electronic device. FIG. 5C illustrates a portion of an example electronic device.

Referring to FIGS. 5A, 5B, and 5C, the electronic device 101 may include a bracket 410 (e.g., the first bracket 215 of FIG. 2C) including the mounting portion 411, a printed circuit board 430, a heat generating component (e.g., the electronic component 401, such as the processor 120 of FIG. 1), a battery 264, and a vapor chamber 500. Hereinafter, redundant descriptions of the components having the same reference numerals as those described in FIG. 4 may be omitted.

As opposed to FIG. 4, the partition wall 415 for supporting the battery 264 of the bracket 410 according to an embodiment may be omitted. In an embodiment, the vapor chamber 500 instead of the heat dissipation sheet 420 may be mounted on the mounting portion 411 of the bracket 410. The vapor chamber 500 may be seated on a portion of the mounting portion 411 in which the printed circuit board 430 and the battery 264 are disposed, and thus an area for heat dissipation of the electronic component 401 may be increased relative to the heat dissipation sheet 420 of FIG. 4.

For example, the vapor chamber 500 may include a first portion 501 disposed on the heat generating component (e.g., the electronic component 401), a second portion 502 interposed between the battery 264 and the mounting portion 411 of the bracket 410, and a third portion 503 extending from the first portion 501 to the second portion 502.

For example, the first portion 501 may be a part on which the printed circuit board 430 is mounted. The first portion 501 may be a part overlapping with the printed circuit board 430 when the printed circuit board 430 is viewed from above (e.g., viewed in the +z direction). For example, the first portion 501 may be covered by the printed circuit board 430. For example, the first portion 501 may be a part at least partially overlapping with the electronic component 401, when the vapor chamber 500 is viewed from above (e.g., viewed in the +z direction). For example, the first portion 501 may be a part that receives heat from the electronic component 401. For example, the first portion 501 may be a part that faces the electronic component 401 or is in contact with the electronic component 401. For example, the first portion 501 may be facing away from the electronic component 401. For example, the first portion 501 may be a part that receives heat from the electronic component 401 through other internal heat dissipation structures (e.g., a shielding sheet 450 or a heat conduction member 460) of the electronic device 101, or contacts the other internal heat dissipation structures. For example, at least a portion of a fluid in a liquid state within the first portion 501 may be vaporized by heat transferred from the electronic component 401 to the first portion 501. The first portion 501 may be configured to diffuse heat released from the electronic component 401 through the third portion 503 and the second portion 502 or to cool the electronic component 401, by vaporizing the fluid in a liquid state within the first portion 501. The first portion 501 may be referred to as an evaporation portion of the vapor chamber 500 and/or a heat source, in that the fluid in a liquid state within a space of an enclosure 510 is vaporized by the heat released from the electronic component 401, but embodiments of the present disclosure are not limited thereto.

For example, the second portion 502 may be spaced apart from the first portion 501. The second portion 502 may be a part disposed between the mounting portion 411 of the bracket 410 and the battery 264. For example, the second portion 502 may be a part covered by the battery 264. For example, the second portion 502 may be a part for fixing the position of the battery 264 in the electronic device 101 by attaching the battery 264. For example, the second portion 502 may be a part configured to be spaced apart from the first portion 501 to have a lower temperature than a temperature of the first portion 501 receiving the heat from the electronic component 401. For example, the second portion 502 may be a part through which the gaseous fluid moved from the first portion 501 to the second portion 502 through the third portion 503 emits heat. The gaseous fluid in the second portion 502 may be liquefied by dissipating heat to the outside of the vapor chamber 500 in the second portion 502. The second portion 502 may be referred to as a condensation portion of the vapor chamber 500, in that the gaseous fluid in the space of the enclosure 510 is liquefied, but embodiments of the present disclosure are not limited thereto. The electronic device 101 may include the vapor chamber 500 including the second portion 502 interposed between the battery 264 and the mounting portion 411, thereby improving the heat dissipation performance of the electronic device 101 for heat emitted from the electronic component 401 and reducing damage to the electronic component 401 and/or one or more other electronic components 402 around the electronic component 401 due to the heat.

For example, the third portion 503 may connect the first portion 501 and the second portion 502. For example, as illustrated in FIG. 5C, unlike FIG. 4, the partition wall 415 of the bracket 410 is omitted, so the third portion 503 may extend from the first portion 501 to the second portion 502. For example, the third portion 503 may be a part that provides a path for fluid movement between the first portion 501 and the second portion 502. The third portion 503 may be disposed between the first portion 501 and the second portion 502. For example, the third portion 503 may extend from the first portion 501 to the second portion 502. For example, the third portion 503 may connect an inner space of the first portion 501 and an inner space of the third portion 503 to provide a flow path (e.g., multiple channels 540) for a gaseous fluid to move from the first portion 501 to the second portion 502, or provide a flow path for passing through a wick structure 520 for the liquid in fluid state to move from the second portion 502 through the wick structure 520 to the first portion 501. For example, the third portion 503 may be omitted. The portions (e.g., the first portion 501, the second portion 502, and/or the third portion 503) of the vapor chamber 500 are illustrated as an example within the present disclosure based on each function and arrangement only for convenience of illustration and explanation, and for example, a part of the third portion 503 may be defined as a part of the first portion 501, and the remaining part of the third portion 503 may be defined as a part of the second portion 502. The third portion 503 may be referred to as a neck portion of the vapor chamber 500 in that it may be a portion connecting the first portion 501 and the second portion 502, but embodiments of the present disclosure are not limited thereto.

The vapor chamber 500 may include an enclosure 510 including a first plate 511 attached to the mounting portion 411 of the bracket 410, and a second plate 512 coupled to the first plate 511 and attached to the battery 264. The vapor chamber 500 may include a fluid in the enclosure 510 and a wick structure 520 disposed in the enclosure 510 and being in contact with the second plate 512.

For example, the first plate 511 and the second plate 512 of the enclosure 510 may be coupled to each other and configured to seal a space for a fluid in the enclosure 510. The fluid in the space may be referred to as a cooling material or refrigeration material in terms of being configured to cool the electronic component 401 through a phase change. The fluid may be vaporized by heat transferred from the electronic component 401 to the vapor chamber 500. The fluid may be liquefied as the heat is released from the vapor chamber 500. The fluid may be, for example, water, but the present disclosure is not limited thereto. For example, the portions (e.g., the first portion 501, the second portion 502, and/or the third portion 503) may diffuse heat emitted from the electronic component 401 by using a phase change of a fluid in the vapor chamber 500, or may form a space for cooling the electronic component 401. For example, the enclosure 510 may define or form those portions (e.g., the first portion 501, the second portion 502, and/or the third portion 503) of the vapor chamber 500. For example, the enclosure 510 may form an exterior of the vapor chamber 500. The enclosure 510 may include a metal having a relatively high thermal conductivity, but the present disclosure is not limited thereto.

For example, the first plate 511 may be a plate supported or attached by the housing 200 (or the bracket 410) of the electronic device 101. The first plate 511 may be a plate facing toward the display 230 of the electronic device 101 (or the first planar portion 231 of the display 230). The second plate 512 coupled to the first plate 511 may be a plate that receives heat from the electronic component 401. For example, the second plate 512 may be a plate facing toward the printed circuit board 430 and/or the battery 264. For example, the second plate 512 may be fastened to the first plate 511. The second plate 512 may provide a space for the fluid in the vapor chamber 500 together with the first plate 511. For example, the second plate 512 may define the portions (e.g., the first portion 501, the second portion 502, and/or the third portion 503) of the enclosure 510 and/or the vapor chamber 500 together with the first plate 511. For example, the second plate 512 may have a shape overlapping with the first plate 511 when the vapor chamber 500 is viewed from above (e.g., in the +z direction), but embodiments of the present disclosure are not limited thereto.

For example, the wick structure 520 may be disposed in the inner space of the vapor chamber 500. The wick structure 520 may be disposed between the first plate 511 and the second plate 512 of the enclosure 510. The wick structure 520 may extend, for example, from the first portion 501 of the vapor chamber 500 to the second portion 502 across the third portion 503. For example, the wick structure 520 may include a porous structure and/or a capillary structure for absorbing a fluid in a liquid state in the vapor chamber 500. For example, the wick structure 520 may be seated on the second plate 512 in the vapor chamber 500. Since the wick structure 520 contacts the second plate 512 disposed toward the electronic component 401, the fluid in a liquid state in the wick structure 520 may be vaporized by heat transferred from the electronic component 401 through the second plate 512. The wick structure 520 may include, for example, at least one from among a mesh wick for absorbing a fluid in a liquid state and a sintering wick, but embodiments of the present disclosure are not limited thereto.

The first plate 511 may include a plurality of pillars 530 protruding from the first plate 511 toward the second plate 512 within the enclosure 510. For example, the plurality of pillars 530 may be in contact with the wick structure 520 by protruding from a bottom surface of the first plate 511 within the vapor chamber 500. For example, the plurality of pillars 530 may support the wick structure 520 and/or the second plate 512 within the enclosure 510 to reduce damage to the enclosure 510 (or the vapor chamber 500) by an external impact.

The first plate 511 (or at least a part of the enclosure 510) of the vapor chamber 500 may be formed from a part of the bracket 410 (or the mounting portion 411), or may be implemented as a part of the bracket 410. However, embodiments of the present disclosure are not limited thereto.

The vape chamber 500 may include a plurality of channels 540 within the vape chamber 500 surrounded by the wick structure 520 and an enclosure 510. The fluid in the vape chamber 500 in a gaseous state may move through the plurality of channels 540. For example, the plurality of channels 540 may be defined by the plurality of pillars 530 protruding from the first plate 511. Like the wick structure 520, the plurality of channels 540 may extend from the first portion 501 of the vape chamber 500 across the third portion 503 to the second portion 502. However, embodiments of the present disclosure are not limited thereto.

The vapor chamber 500 may be configured to diffuse heat transferred from the heat generating component (e.g., the electronic component 401) to the first portion 501, through the third portion 503, to the second portion 502. For example, the first portion 501 of the vapor chamber 500 may receive the heat emitted from the electronic component 401. Through the heat transferred to the first portion 501, the fluid may be vaporized from the wick structure 520 in the first portion 501. The fluid vaporized may diffuse to the second portion 502, through the third portion 503, via the plurality of channels 540 in the vapor chamber 500. The gaseous fluid that has absorbed the heat may diffuse the heat by diffusing from the first portion 501 through the third portion 503 to the second portion 502. The fluid may cool by dissipating the heat to the surroundings of the vapor chamber 500, as it moves away from the electronic component 401. The gaseous fluid may be condensed in the third portion 503 by being cooled while moving to the second portion 502 through the third portion 503. The condensed fluid in a liquid state may be absorbed into the wick structure 520 in the vapor chamber 500. The fluid in a liquid state may move back from the second portion 502 through the wick structure 520, through the third portion 503, to the first portion 501. However, embodiments of the present disclosure are not limited thereto.

According to an embodiment, an area A2 of the second portion 502 of the vapor chamber 500 may be greater than an area A1 of the first portion 501 of the vapor chamber 500. For example, a width of the second portion 502 may be greater than a width of the first portion 501. For example, an internal volume of the second portion 502 may be greater than an internal inner volume of the first portion 501. For example, when the mounting portion 411 is viewed from above (e.g., viewed in the +z direction), the area A1 of the first portion 501 overlapping the electronic component 401 may be less than the area A2 of the second portion 502 overlapping the battery 264. Since the area A2 of the second portion 502 is greater than the area A1 of the first portion 501, the vapor chamber 500 may diffuse the heat transferred from the electronic component 401 to the first portion 501, through the third portion 503, to the second portion 502. By diffusing the heat to the second portion 502, the vapor chamber 500 can improve the heat dissipation performance of the electronic device 101 for the heat emitted from the electronic component 401 and/or reduce damage to the electronic component 401 and/or one or more other electronic components 402 around the electronic component 401 due to the heat.

According to an embodiment, the heat dissipation sheet 420 of FIG. 4 may be disposed instead of the vapor chamber 500. For example, the heat dissipation sheet 420 of FIG. 4 may be disposed instead of those portions (e.g., the first portion 501, the second portion 502, and/or the third portion 503) of the vapor chamber 500. At least a portion of the heat dissipation sheet 420 may be interposed between the battery 264 and the mounting portion 411. The remaining portion of the heat dissipation sheet 420 may be disposed between the printed circuit board 430 (or the heat generating component (e.g., the electronic component 401)), but embodiments of the present disclosure are not limited thereto.

The electronic device 101 may include a display 230 disposed on the bracket 410. The vapor chamber 500 may be spaced apart from the display 230 by the bracket 410. For example, the mounting portion 411 of the bracket 410 may define a first surface 411a to which the vapor chamber 500 is attached and a second surface 411b opposite to the first surface 411a. The second surface 411b may be arranged to face the display 230 of the electronic device 101. For example, at least a portion of the mounting portion 411 of the bracket 410 may be disposed between the display 230 and the vapor chamber 500. The remaining portion of the mounting portion 411 may be disposed between the display 230 and the battery 264. As the vapor chamber 500 and/or the battery 264 is separated from the display 230 by the bracket 410, the electronic device 101 may improve visibility of the display 230 and reduce damage to the display 230 due to an external impact.

Referring to FIG. 5B, the electronic device 101 may include a housing 200 including a first housing part 210 and a second housing part 220, defining a bracket 410, and a hinge structure 250 rotatably coupling the first housing part 210 and the second housing part 220. The display 230 may include a first planar portion 231 coupled to the first housing part 210 and disposed on the mounting portion 411 of the bracket 410, a second planar portion 232 coupled to the second housing part 220 and spaced apart from the first planar portion 231, and a foldable portion 233 extending from the first planar portion 231 to the second planar portion 232 and deformable by the hinge structure 250. For example, referring to FIGS. 2A to 3B together, the vapor chamber 500, the printed circuit board 430, and the battery 264 may be disposed within the first housing 210 of the housing 200. The bracket 410 that provides the mounting portion 411 on which the vapor chamber 500 is seated may be referred to as the first bracket 215 of FIG. 2C. For example, the vapor chamber 500, the printed circuit board 430, and the battery 264 may be disposed between the bracket 410 and the first cover 216 of the first housing 210. However, embodiments of the present disclosure are not limited thereto, and for example, the structure in which the vapor chamber 500, the battery 264, and the printed circuit board 430 with the electronic component 401 mounted therein are arranged in the first housing 210 may be similarly applied to structures and/or components between the second bracket 227 and the second cover 228 of the second housing 220 that is rotatably coupled to the first housing 210.

According to an embodiment, the electronic component 401 may be disposed on one surface 430a facing the bracket 410. For example, the electronic device 101 may include a shield can 440 disposed on the one surface 430a and surrounding the electronic component 401. The shield can 440 may include a through hole 445 formed on the electronic component 401. For example, the shield can 440 may be coupled to the one surface 430a, which may be a part of the printed circuit board 430 to which the electronic component 401 is coupled, thereby shielding the electronic component 401. The through hole 445 of the shield can 440 may overlap with the electronic component 401, when the electronic component 401 is viewed from above (e.g., viewed from +z direction). The through hole 445 may pass through the heat conduction member 460 attached to the electronic component 401. For example, the through hole 445 may be a path for discharging at least a portion of heat emitted from the electronic component 401 through the heat conduction member 460 disposed on the electronic component 401.

For example, the shield can 440 may be connected to a ground in the electronic device 101. For example, the shield can 440 may be electrically connected to the ground of the electronic device 101 through the printed circuit board 430. The shield can 440 may be connected to the ground to emit electromagnetic waves emitted from the electronic component 401 to the ground. By emitting the electromagnetic waves to the ground, the shield can 440 may reduce performance degradation of one or more other electronic components 402 around the electronic component 401 by the electromagnetic waves.

According to an embodiment, the electronic device 101 may include a shielding sheet 450 which covers the through hole 445 of the shield can 440, by being attached onto the shield can 440, and a heat conduction member 460 which is interposed between the electronic component 401 and the shielding sheet 450 through the through hole 445. For example, the shielding sheet 450 may be disposed between the shield can 440 and the vapor chamber 500 (or the first portion 501 of the vapor chamber 500). The shielding sheet 450 may be in contact with the heat conduction member 460 which has passed through the through hole 445. The shielding sheet 450 may shield the electronic component 401 together with the shield can 440, by covering the through hole 445. For example, the shielding sheet 450 may be electrically connected to the shield can 440 by including a conductive material. The shielding sheet 450 may be configured to transmit electromagnetic waves emitted from the electronic component 401 to the shield can 440 connected to the ground, but the embodiment is not limited thereto.

For example, the heat conduction member 460 may be attached on the electronic component 401. The heat conduction member 460 may be interposed between the electronic component 401 and the shielding sheet 450. The heat conduction member 460 may be in contact with the shielding sheet 450 through the through hole 445 of the shield can 440. For example, the heat conduction member 460 may be in contact with the electronic component 401 and the shielding sheet 450. For example, the heat conduction member 460 may transfer at least part of the heat emitted from the electronic component 401 to the shielding sheet 450 on the heat conduction member 460 and/or the first portion 501 of the vapor chamber 500 through conduction heat transfer. For example, the heat conduction member 460 may be attached to the shielding sheet 450 to be fastened in between the shielding sheet 450 and the electronic component 401. However, embodiments of the present disclosure are not limited thereto, and for example, one or more other heat conduction members may be disposed between the vapor chamber 500 and the shielding sheet 450.

For example, the heat conduction member 460 may penetrate (e.g., be within) at least a portion of the through hole 445 of the shield can 440. For example, the heat conduction member 460 may be attached to the shielding sheet 450 covering the through hole 445 by passing through the through hole 445. For example, the heat conduction member 460 may provide a path for transferring the heat emitted from the electronic component 401 through the through hole 445 to the shielding sheet 450 and the vapor chamber 500. For example, the heat conduction member 460 may include a material having a relatively high thermal conductivity. The heat conduction member 460 may be referred to as a thermal interface material (TIM) in terms of being interposed between the electronic component 401 and the shielding sheet 450, but the present disclosure is not limited thereto. The electronic device 101 may include the heat conduction member 460 that transfers at least part of the heat released from the electronic component 401 to the shielding sheet 450 and/or the vapor chamber 500 through the through hole 445 of the shield can 440, thereby reducing performance degradation of the electronic component 401 surrounded by the shield can 401 due to the heat released from the electronic component 401.

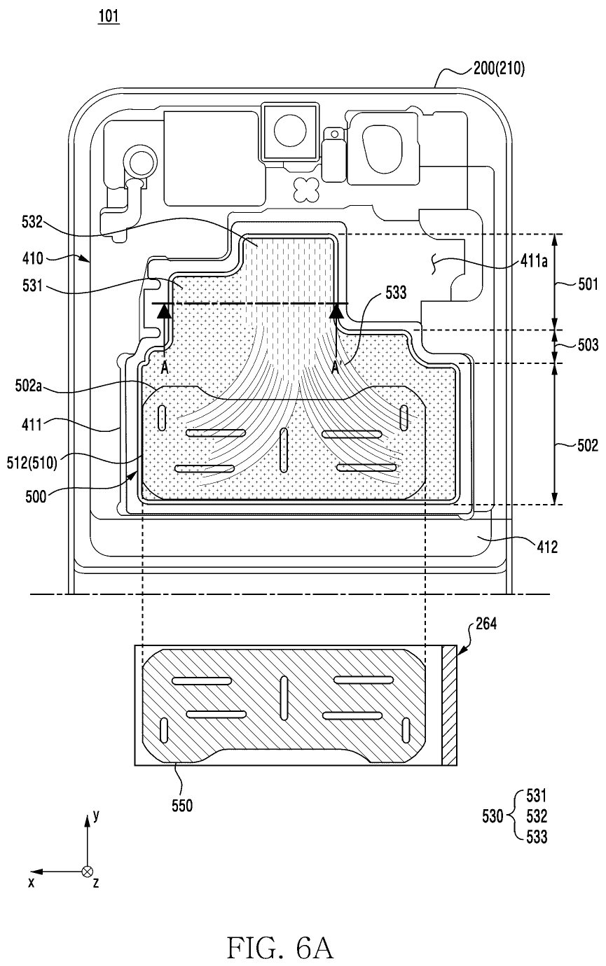

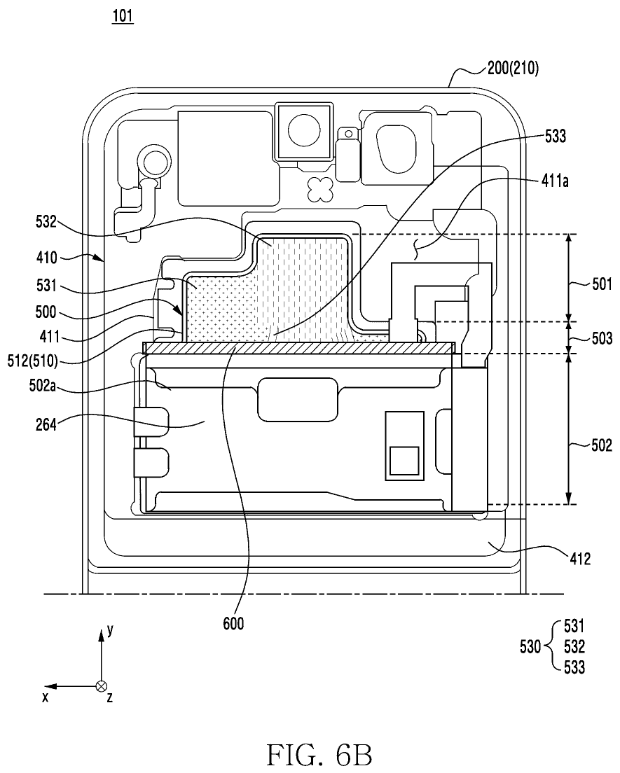

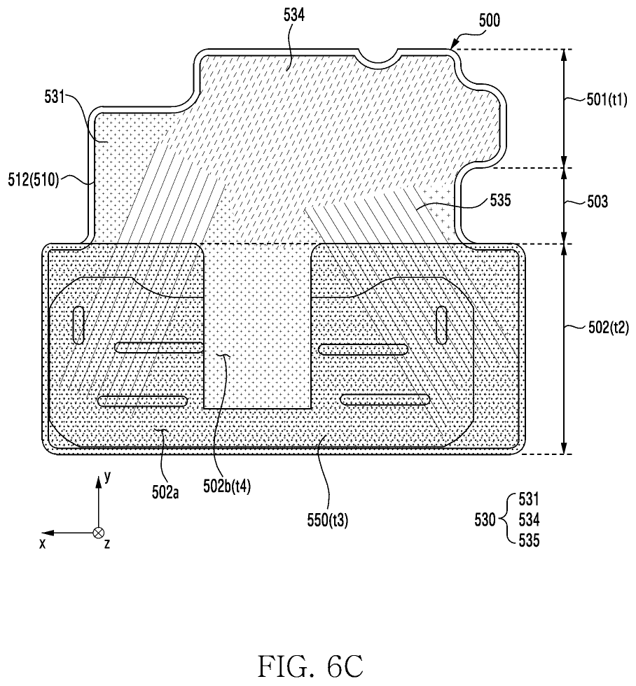

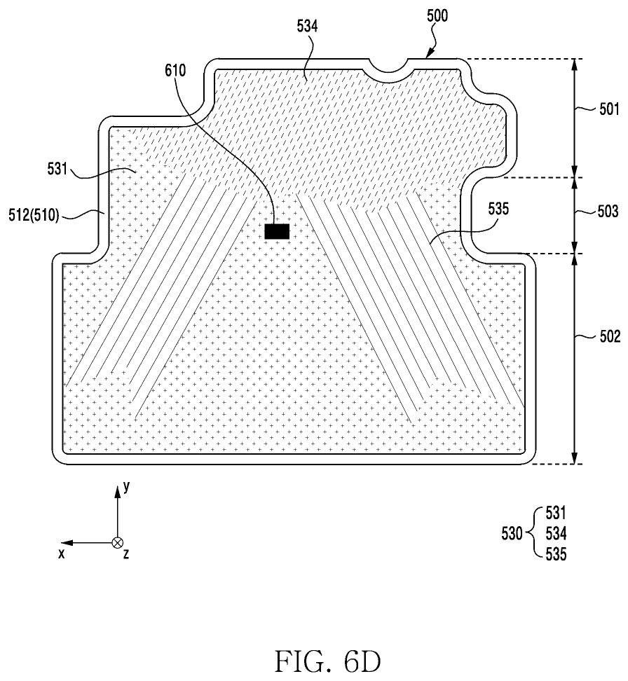

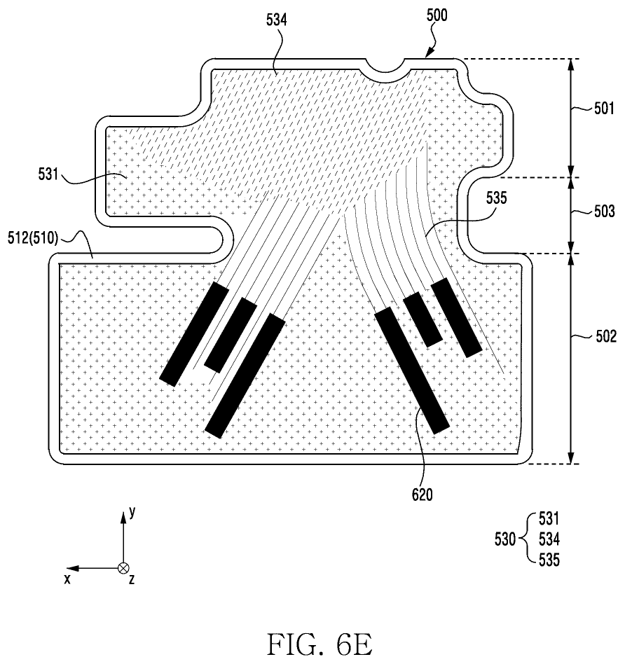

According to an embodiment, the electronic device 101 may include an adhesive member 550 for attaching the battery 264 to the vapor chamber 500. For example, the adhesive member 550 may be interposed between the battery 264 and the second portion 502 of the vapor chamber 500. With the adhesive member 550, the battery 264 may be fixed on the second plate 512 of the vapor chamber 500. For example, to replace the vapor chamber 500 and/or the battery 264, it may be required to separate the battery 264 from the vapor chamber 500 or to compress the battery 264 onto the vapor chamber 500 with the adhesive member 550. While separating the battery 264 from the vapor chamber 500 or compressing the battery 264 onto the vapor chamber 500, the vapor chamber 500 may be damaged due to such adhesion or compression of the adhesive member 550. Further, as the thickness of the vapor chamber 500 is relatively reduced by the thickness of the adhesive member 550, the performance of the vapor chamber 500 may be deteriorated. The electronic device 101 may include a structure for reducing damage to the vape chamber 500 and improving the performance of the vape chamber 500. The above structure will be described by way of an example with reference to illustration of FIG. 6A or its subsequent drawings.

FIGS. 6A and 6B illustrate a part of an example electronic device. FIGS. 6C, 6D, and 6E illustrate a vapor chamber of an example electronic device.

Referring to FIGS. 6A, 6B, 6C, 6D, and 6E, the electronic device 101 may include a bracket 410 (e.g., the first bracket 215 of FIG. 2C) inclusive of a mounting portion 411, a printed circuit board (e.g., the printed circuit board 430 of FIG. 5B) disposed facing the bracket 410, a heat generating component (e.g., the processor 120 of FIG. 1, or the heat generating component (e.g., the electronic component 401) of FIG. 5B) disposed on one surface (e.g., the one surface 430a of FIG. 5C) facing toward the bracket 410 of the printed circuit board 430, a battery 264 spaced apart from the heat generating component (e.g., the electronic component 401) and received in the bracket 410, and a vapor chamber 500 seated in the mounting portion 411 of the bracket 410. The vapor chamber 500 may include a first portion 501 disposed on the heat generating component (e.g., the electronic component 401), a second portion 502 between the battery 264 and the mounting portion 411, and a third portion 503 extending from the first portion 501 to the second portion 502. However, embodiments of the present disclosure are not limited thereto, and the electronic device 101 may include the structures and/or configurations (e.g., the display 230, the shield can 440, the shielding sheet 450, or the heat conduction member 460) illustrated and described with reference to FIGS. 5A to 5C. For example, the housing 200 to be illustrated and described in FIGS. 6A and 6B may be referred to as the first housing 210 of the example foldable electronic device illustrated and described with reference to FIGS. 2A to 5C. The first housing 210 may be rotatably coupled to the second housing (e.g., the second housing 220 of FIG. 2A) by means of a hinge structure (e.g., the hinge structure 250 of FIG. 2C), but embodiments of the present disclosure are not limited thereto, and in the following description, redundant descriptions of the structure and configurations with the same reference numerals as those described in FIGS. 2A to 5C may be omitted.

Referring to FIG. 6A, a battery 264 may be attached to the second portion 502 of the vapor chamber 500. For example, after the adhesive member 550 is attached to the battery 264, the adhesive member 550 may then be attached to the enclosure 510 of the vapor chamber 500, so that the battery 264 may be attached to the vapor chamber 500 through the adhesive member 550. For example, the second plate 512 of the enclosure 510 included in the second portion 502 of the vapor chamber 500 may include an adhesive surface 502a to which the adhesive member 550 is attached. The adhesive surface 502a may have a shape corresponding to the shape of the adhesive member 550 attached to the battery 264. For example, the adhesive surface 502a may have the shape corresponding to the shape of the adhesive member 550, thereby guiding a position for the battery 264 to be attached on the second portion 502 of the vapor chamber 500.

Referring to FIG. 6B, the battery 264 may be attached to the second portion 502 of the vapor chamber 500. According to an embodiment, the electronic device 101 is disposed on the third portion 503 of the vapor chamber 500 and may include a fastener 600 configured to fix the vapor chamber 500 to the bracket 410 by coupling to the bracket 410. For example, the fastener 600 may be coupled to the mounting portion 411 of the bracket 410 to fix the third portion 503 of the vapor chamber 500 to the mounting portion 411. For example, the fastener 600 may support the battery 264 by contacting the battery 264. The fastener 600 may, for example, press the battery 264 against the sidewall 412 of the bracket 410. The fastener 600 may support the battery 264, thereby reducing the battery 264 from being separated from a space between the fastener 600 and the sidewall 412 due to any external impact. However, embodiments of the present disclosure are not limited thereto.

Referring to FIG. 6C, at least a portion of the vapor chamber 500 may have different thicknesses. For example, the thickness t₁ of the first portion 501 of the vapor chamber 500 may be greater than the thickness t₂ of the second portion 502 of the vapor chamber 500. For example, a difference between the thickness t₁ of the first portion 501 and the thickness t₂ of the second portion 502 may correspond to the thickness of the adhesive member 550, but embodiment of the present disclosure are not limited thereto. For example, the enclosure 510 may include a step difference in the third portion 503. When the enclosure 510 includes such a step difference, the thickness of the inner space of the first portion 501 may be configured to be greater than the thickness of the inner space of the second portion 502. Since the vapor chamber 500 is configured such that the thickness t₁ of the first portion 501 is greater than the thickness t₂ of the second portion 502, the performance of the vapor chamber 500 may be improved. However, embodiments of the present disclosure are not limited thereto.

For example, the second plate 512 located in the second portion 502 may include an adhesive surface 502a to which the adhesive member 550 is attached, and a protruding surface 502b that protrudes from the adhesive surface 502a toward the battery 264 to contact the battery 264. The thickness t₃ of the adhesive member 550 may correspond to the thickness t₄ of the protruding surface 502b. For example, the adhesive surface 502a may be recessed from the protruding surface 502b. The vapor chamber 500 may be configured such that the second portion 502 has different thicknesses, thereby improving the performance of the vapor chamber 500. However, embodiments of the present disclosure are not limited thereto. According to embodiments, the thicknesses (e.g., the thicknesses t₁, t₁, t₃, and t₄) may be in the z direction.

Referring to FIGS. 6A to 6E, a plurality of pillars 530 within a vapor chamber 500 may have various shapes and/or patterns. For example, referring to FIGS. 6A and 6B, the first plate 511 of the enclosure 510 may include first pillars 531, second pillars 532, and third pillars 533. For example, each of the first pillars 531 may have a circular shape when viewing the enclosure 510 from above (e.g., when viewed in +z direction). The second pillars 532 may form a pattern arranged in a direction (e.g., −y direction) from the first portion 501 toward the second portion 502, thereby forming a flow path (or a plurality of channels 540 of FIG. 5C) of a gaseous fluid in the vapor chamber 500 moving from the first portion 501 to the second portion 502. For example, the third pillars 533 may be formed in the third portion 503 and the second portion 502. The third pillars 533 may extend from the third portion 503 to the second portion 502 to form a diffusion path (or the plural channels 540 of FIG. 5C) of a gaseous fluid in the vapor chamber 500 moving from the third portion 503 to the second portion 502. For example, each of the third pillars 533 may be at least partially bent. For example, referring to FIGS. 6D and 6E, a plurality of pillars 530 may include fourth pillars 534 forming a pattern arranged to be inclined with respect to a direction facing from the first portion 501 toward the second portion 502 (e.g., −y direction), and fifth pillars 535 extending from the third portion 503 to the second portion 502. Unlike the third pillars 533, the fifth pillars 535 may have a straight shape. However, embodiments of the present disclosure are not limited to thereto. The plurality of pillars 530 may include pillars having different shapes and/or patterns, thereby improving the performance of the vapor chamber 500.

Referring to FIGS. 6D and 6E, at least some of the plurality of pillars 530 may be welded to the second plate 512. For example, the vapor chamber 500 may include at least one welding portion in which the plurality of pillars 530 and the second plate 512 are welded to each other. For example, referring to FIG. 6D, the third portion 503 of the vapor chamber 500 may include a first welding portion 610 in which at least some of the first pillars 531 and the second plate 512 are welded to each other. The first welding portion 610 may be, for example, disposed in the third portion 503 connected to the second portion 502 of the vapor chamber 500. For example, referring to FIG. 6E, the second portion 502 of the vapor chamber 500 may include a second welding portion 620 in which at least some of the fifth pillars 535 and the second plate 512 are welded to each other. The second welding portion 620 may be disposed in the second portion 502 of the vapor chamber 500 to which the battery 264 is attached. However, embodiments of the present disclosure are not limited thereto. The vapor chamber 500 includes one or more welded portions in which at least some of the plurality of pillars 530 and the second plate 512 are welded to each other in the enclosure 510, thereby reducing damage to the vapor chamber 500 while the battery 264 is pressed onto the vapor chamber 500 or separated from the vapor chamber 500.

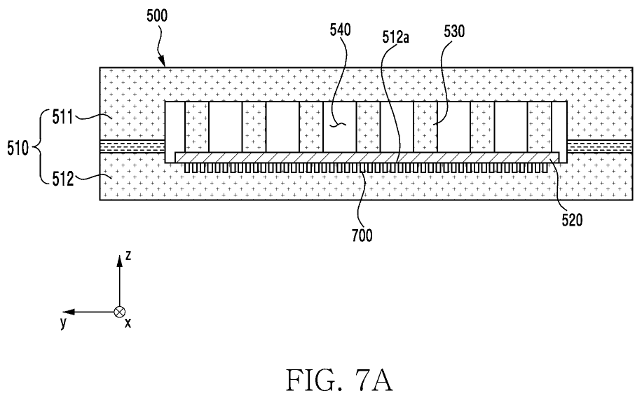

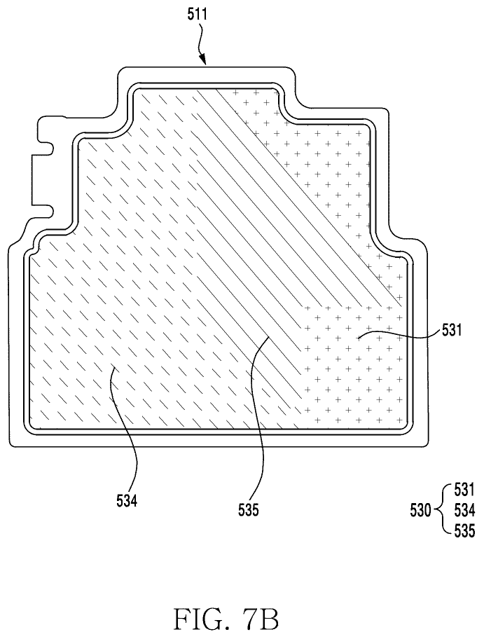

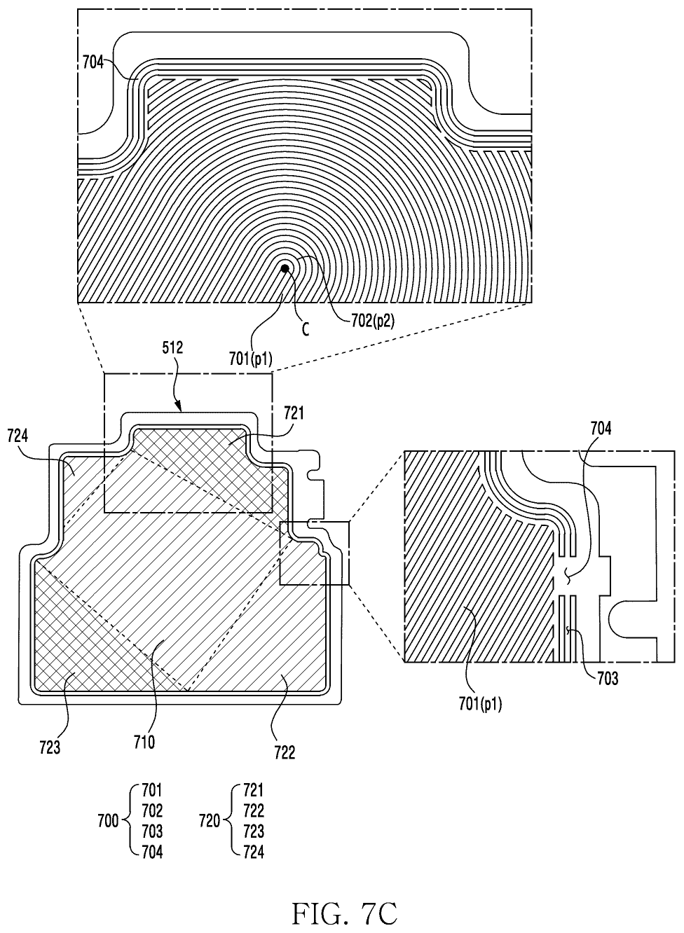

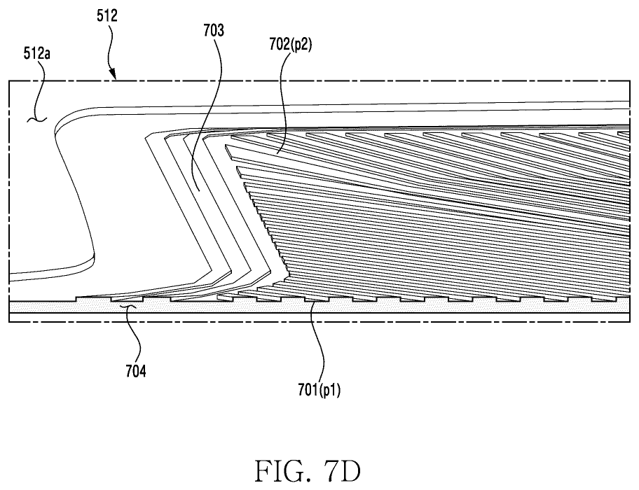

FIG. 7A is a cross-sectional view of a vapor chamber of an example electronic device taken along a line A-A′ of FIG. 6A. FIG. 7B is a top plan view of a first plate of a vapor chamber of an example electronic device. FIG. 7C is a top plan view of a second plate of a vapor chamber of an example electronic device. FIG. 7D illustrates a portion of a second plate of a vapor chamber of an example electronic device.

Referring to FIGS. 7A, 7B, 7C, and 7D, the vapor chamber 500 (or then enclosure 510 of the vapor chamber 500) disposed within the electronic device 101 illustrated and described with reference to FIGS. 5A to 6B is illustrated and described. The electronic device 101 may include a bracket (e.g., the first bracket 215 of FIG. 2C, the bracket 410 of FIG. 5A) including a mounting portion (e.g., the mounting portion 411 of FIG. 5A), a printed circuit board (e.g., the printed circuit board 430 of FIG. 5B) disposed toward the bracket 410, a heat generating component (e.g., the processor 120 of FIG. 1, the heat generating component (e.g., the electronic component 401) of FIG. 5B) disposed on one surface (e.g., the one surface 430a of FIG. 5C) facing toward the bracket 410 of the printed circuit board 430, and a battery 264 accommodated in the bracket 410 and spaced apart from the heat generating component (e.g., the electronic component 401). The vapor chamber 500 may be seated on the mounting portion 411 of the bracket 410. The vapor chamber 500 may include a first portion (e.g., the first portion 501 of FIG. 5A) disposed on the heat generating component (e.g., the electronic component 401), a second portion (e.g., the second portion 502 of FIG. 5A) interposed between the battery 264 and the mounting portion 411, and a third portion (e.g., the third portion 503 of FIG. 5A) extending from the first portion 501 to the second portion 502. However, embodiments of the present disclosure are not limited thereto, and the electronic device 101 may include the structures and/or configurations illustrated and described with reference to FIGS. 5A to 6E (e.g., the housing 200, the display 230, the hinge structure 250, the shield can 440, the shielding sheet 450, the heat conduction member 460, or the fastener 600). However, embodiments of the present disclosure are not limited thereto, and in the following description, redundant descriptions of configurations with the same reference numerals as those described in FIGS. 2A to 6E may be omitted.

The vapor chamber 500 may include an enclosure 510 including a first plate 511 attached to the mounting portion 411 of the bracket 410 and a second plate 512 coupled to the first plate 511 and attached to the battery 264. The vapor chamber 500 may include a fluid in the enclosure 510, and a wick structure 520 disposed in the enclosure 510 and in contact with the second plate 512. The first plate 511 may include a plurality of pillars 530 protruding from the first plate 511 toward the second plate 512 within the vapor chamber 500. For example, the plurality of pillars 530 of the first plate 511 may include pillars (e.g., the first pillars 531, the fourth pillars 534, and the fifth pillars 535) having different shapes and/or patterns, as shown in FIG. 7B.

According to an embodiment, the second plate 512 may include a plurality of flow paths 700 recessed from a bottom surface 512a of the second plate 512 to move a fluid in a liquid state between the wick structure 520 and the second plate 512. For example, the plurality of flow paths 700 may be indented from the bottom surface 512a of the second plate 512 in the vapor chamber 500. For example, the plurality of flow paths 700 may be covered by the wick structure 520. For example, the plurality of flow paths 700 may be configured to move the fluid in a liquid state within the plurality of flow paths 700 by forming a microtubule structure. The plurality of flow paths 700 may be, for example, formed through an etching process of the enclosure 510 (or the second plate 512), but embodiments of the present disclosure are not limited thereto.

Referring to FIGS. 7C and 7D, the second plate 512 may include corner portions 720 disposed along a periphery of the second plate 512 and a center portion 710 surrounded by the corner portions 720. The plurality of flow paths 700 may be connected to connected to first flow paths 701 formed in the center portion 710 and having a first pattern p1, and second flow paths 702 formed in at least some of the corner portions 720 and connected to the first flow paths 701 and having a second pattern p2 different from the first pattern p1. For example, the first flow paths 701 may form the first pattern p1 of a linear pattern. The first flow paths 701 may be formed, for example, in the center portion 710 of the second plate 712, and a second corner portion 722 and a fourth corner portion 724 among corner portions (e.g., a first corner portion 721, the second corner portion 722, a third corner portion 723, and the fourth corner portion 724). For example, the second flow paths 702 may be formed in a first corner portion 721 and a third corner portion 723 facing away from the first corner portion 721 among the corner portions (e.g., the first corner portion 721, the second corner portion 722, the third corner portion 723, and the fourth corner portion 724), as illustrated. The second flow paths 702 may form, for example, a second pattern p2 of a radial pattern, which is different from the first pattern p1 of a linear pattern. The second plate 712 may include the second flow paths 702 forming a radial pattern in at least a portion of the corner portions 720, thereby reducing stagnation of a fluid in a liquid state in the corner portions 720, and improving performance of the vapor chamber 500.

The plurality of flow paths 700 may include one or more third flow paths 703 formed along the periphery of the second plate 512 and configured to circulate a fluid in a liquid state along the periphery of the second plate 512, and one or more fourth flow paths 704 that provide a passage for connecting at least some of the first flow paths 701 and the second flow paths 702 to the one or more third flow paths 703.

For example, one or more third flow paths 703 may surround the first flow paths 701 and the second flow paths 702. For example, the one or more third flow paths 703 may have a shape corresponding to the shape of a periphery of the second plate 512. The one or more third flow paths 703 may be formed along the periphery of the second plate 512 to circulate a fluid in a liquid state in the vapor chamber 500 along the periphery. For example, one or more fourth flow paths 704 may connect the first flow paths 701 and/or the second flow paths 702 to one or more third flow paths 703. The one or more fourth flow paths 704 may be formed by removing a portion of the bottom surface 512a of the second plate 512 forming one or more third flow paths 703, but embodiments of the present disclosure are not limited thereto. The enclosure 510 of the vapor chamber 500 may improve the performance of the vapor chamber 500 owing to including a plurality of flow paths 700 for moving the fluid in a liquid state in the vapor chamber 500.

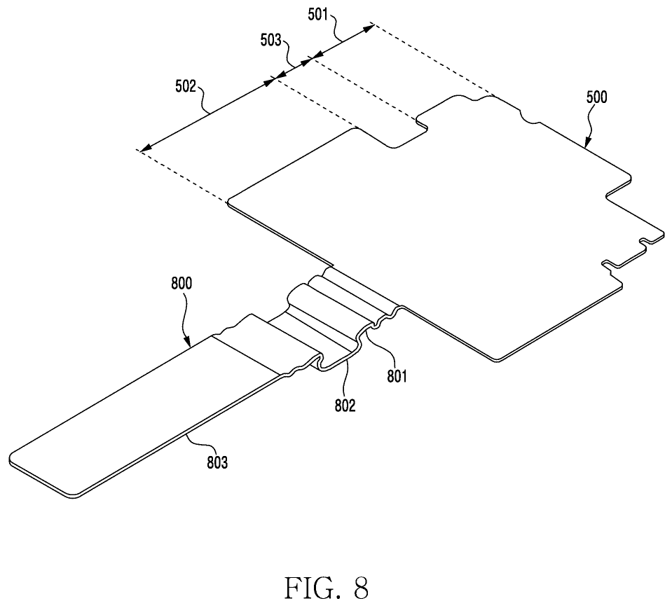

FIG. 8 illustrates a structure for heat dissipation of an example electronic device.

Referring to FIG. 8, the structure for heat dissipation of the electronic device 101 including the vapor chamber 500 disposed within the electronic device 101 illustrated and described in FIGS. 5A to 6B will be illustrated and described by way of an example. The electronic device 101 may include a bracket (e.g., the first bracket 215 of FIG. 2A, the bracket 410 of FIG. 5A) including a mounting portion (e.g., the mounting portion 411 of FIG. 5A), a printed circuit board (e.g., the printed circuit board 430 of FIG. 5B) disposed toward the bracket 410, a heat generating component (e.g., the processor 120 of FIG. 1, the heat generating component (e.g., the electronic component 401) of FIG. 5B) disposed on one surface (e.g., one surface 430a of FIG. 5C) facing toward the bracket 410 of the printed circuit board 430, and a battery (e.g., the battery 264 of FIG. 2C) spaced apart from the heat generating component (e.g., the electronic component 401) and accommodated in the bracket 410. The vapor chamber 500 may be seated on the mounting portion 411 of the bracket 410. The vapor chamber 500 may include a first portion 501 disposed on the heat generating component (e.g., the electronic component 401), a second portion 502 interposed between the battery 264 and the mounting portion 411, and a third portion 503 extending from the first portion 501 to the second portion 502. However, embodiments of the present disclosure are not limited thereto, and the electronic device 101 may include the structures and/or configurations illustrated and/or described with reference to FIGS. 5A to 7D (e.g., the housing 200, the display 230, the hinge structure 250, the shield can 440, the shield can 450, the heat conduction member 460, the fastener 600, or a plurality of flow paths 700 of the vapor chamber 500). However, embodiments of the present disclosure are not limited thereto, and in the following description, redundant descriptions of configurations with the same reference numerals as those described in FIGS. 2A to 6E may be omitted.

The housing 200 of the electronic device 101 may include a first housing (e.g., the first housing 210 of FIG. 2A), defining the bracket 410 on which the vapor chamber 500 is mounted, and a second housing (e.g., the second housing 220 of FIG. 2A). The electronic device 101 may include a hinge structure 250 that rotatably couples the first housing 210 and the second housing 220. The electronic device 101 may include a heat dissipation member 800 extending into the second housing 220 across the hinge structure 250 from the second portion 502 of the vapor chamber 500.

For example, the heat dissipation member 800 may include a first heat dissipation part 801 connected to the vapor chamber 500 (or the second portion 502 of the vapor chamber 500), a second heat dissipation part 802 connected to the first heat dissipation part 801 and disposed on the hinge structure 250, and a third heat dissipation part 803 connected to the second heat dissipation part 802 and disposed in the second housing 220. The first heat dissipation part 801 may be disposed, for example, in the first housing 210 in which the vapor chamber 500 is disposed. The second heat dissipation part 802 may be attached to at least a part of the hinge structure 250 to distribute heat transferred from the vapor chamber 500 to the first heat dissipation part 801 through the hinge structure 250. The third heat dissipation part 803 may be attached to a portion of the second housing 220 (e.g., the second bracket 217 of FIG. 2C), thereby distributing the heat transferred from the second heat dissipation part 802 through the second housing 220. However, embodiments of the present disclosure are not limited thereto. The electronic device 101 may improve the heat dissipation performance of the electronic device 101 for the heat emitted from the electronic component 401 within the electronic device 101, owing to including the heat dissipation member 800 connected to the vapor chamber 500.

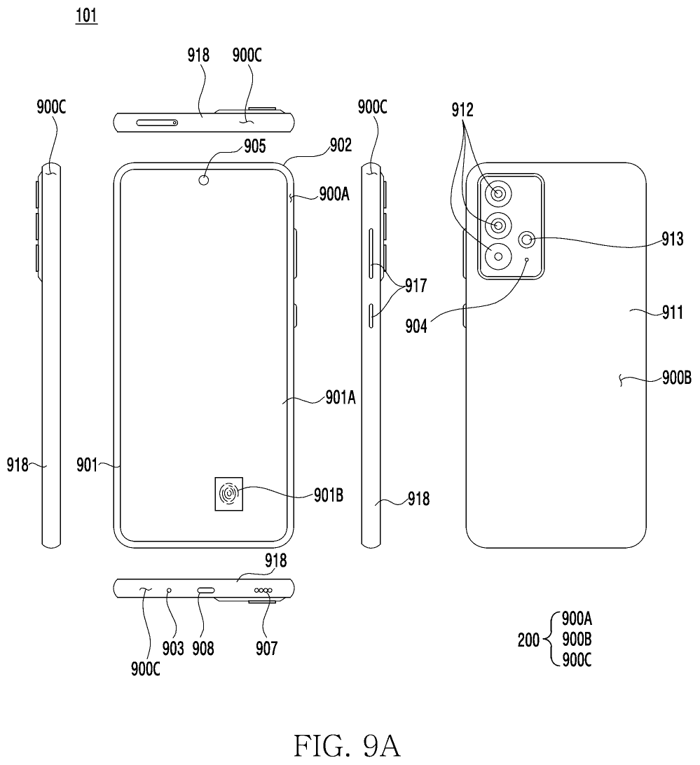

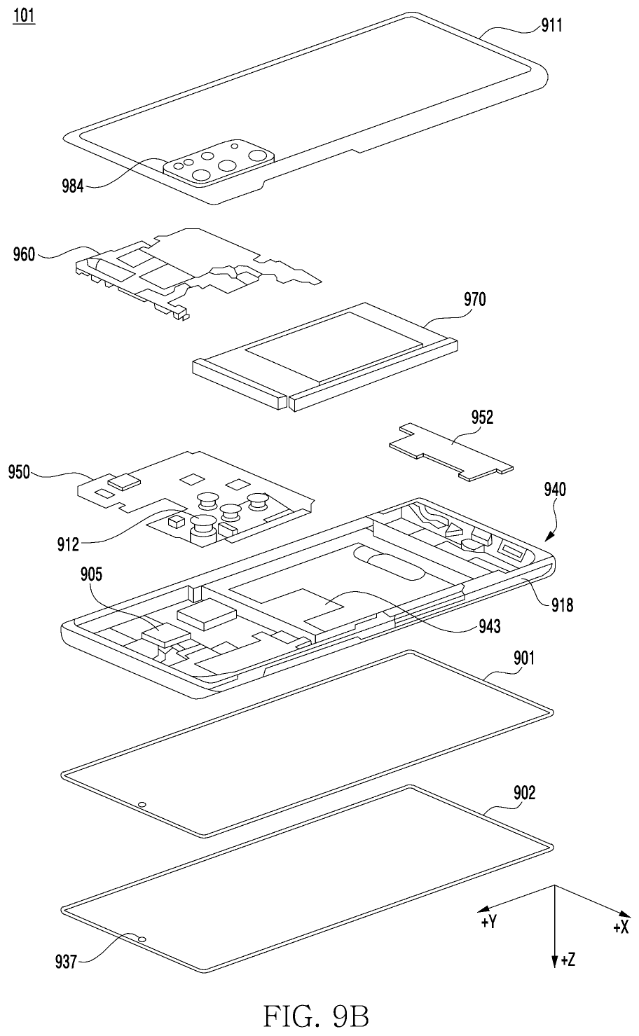

FIG. 9A is a diagram illustrating an example electronic device.

Referring to FIG. 9A, the electronic device 101 according to an embodiment may include a housing 200 that forms an exterior appearance of the electronic device 101. For example, the housing 200 may include a front surface 900A, a rear surface 900B, and a side surface 900C that surrounds a space between the front surface 900A and the rear surface 900B. According to an embodiment, the housing 200 may also refer to a structure forming at least a portion of the front surface 900A, the rear surface 900B, and/or the side surface 900C.

The electronic device 101 may include a front plate 902 that may be substantially transparent. According to an embodiment, the front plate 902 may form at least a portion of the front surface 900A. According to an embodiment, the front plate 902 may include, for example, a glass plate including various coating layers or a polymer plate, but the disclosure is not limited thereto.

The electronic device 101 may include a rear plate 911 that may be substantially opaque. According to an embodiment, the rear plate 911 may form at least a portion of the rear surface 900B. According to an embodiment, the rear plate 911 may be formed of coated or colored glass, ceramic, polymer, metal (e.g., aluminum, stainless steel (STS), or magnesium), or a combination of at least two of the above materials.

The electronic device 101 may include a side bezel structure (or side member) 918. According to an embodiment, the side bezel structure 918 may be coupled with the front plate 902 and/or the rear plate 911 to form at least a portion of the side surface 900C of the electronic device 101. For example, the side bezel structure 918 may form the entire side surface 900C of the electronic device 101, and for another example, the side bezel structure 918 may form the side surface 900C of the electronic device 101 together with the front plate 902 and/or the rear plate 911.

When the side surface 900C of the electronic device 101 is partially formed by the front plate 902 and/or the rear plate 911, the front plate 902 and/or the rear plate 911 may include an area that is bent toward the rear plate 911 and/or the front plate 902 at its periphery and seamlessly extends. For example, an extending area of the front plate 902 and/or the rear plate 911 may be located at both ends of a long peripheral edge of the electronic device 101, but the present disclosure is not limited to the above-described examples.

The side bezel structure 918 may include a metal and/or a polymer. According to an embodiment, the rear plate 911 and the side bezel structure 918 may be integrally formed and may include the same material (e.g., a metallic material such as aluminum), but the present disclosure is not limited thereto. For example, the rear plate 911 and the side bezel structure 918 may be formed in separate configurations or may include different materials.

The electronic device 101 may include at least one from among a display 901, audio modules (e.g., a first microphone hole 903, a second microphone hole 904, and a speaker hole 907), a sensor module, camera modules (e.g., the first camera 905, the second camera 912, and the flash 913), a key input device 917, a light emitting device, and/or a connector hole 908. According to an embodiment, the electronic device 101 may omit at least one (e.g., a key input device 917 and/or a light emitting device) of the above components, or may additionally include other components.

The display 901 may be visually exposed through a corresponding portion of the front plate 902. For example, at least a portion of the display 901 may be viewable through the front plate 902 forming the front surface 900A. For example, the display 901 may be disposed on a rear surface of the front plate 902.

The outer shape of the display 901 may be formed substantially the same as the outer shape of the front plate 902 adjacent to the display 901. According to an embodiment, in order to expand an area in which the display 901 is visually exposed, a distance between an outer periphery of the display 901 and an outer periphery of the front plate 902 may be formed substantially the same.

The display 901 (or the front surface 900A of the electronic device 101) may include a screen display area 901A. According to an embodiment, the display 901 may provide visual information to a user through the screen display area 901A. When the front surface 900A is viewed from the front, the screen display area 901A is illustrated to be spaced apart from the outside of the front surface 900A and positioned inside the front surface 900A, but the present disclosure is not limited thereto. For example, when the front surface 900A is viewed from the front, at least a portion of a periphery part of the screen display area 901A may substantially coincide with a periphery part of the front surface 900A (or the front plate 902).

The screen display area 901A may include a sensing area 901B configured to obtain a user's biometric information. Here, the meaning of “the screen display area 901A including the sensing area 901B” may be understood as at least a part of the sensing area 901B overlapping with the screen display area 901A. For example, the sensing area 901B may refer to an area capable of displaying visual information on the display 901, as in other areas of the screen display area 901A, and additionally obtaining the user's biometric information (e.g., fingerprint). According to an embodiment, the sensing area 901B may be formed in the key input device 917.

The display 901 may include an area in which a first camera 905 is located. According to an embodiment, an opening is formed in the area of the display 901, and the first camera 905 (e.g., a punch hole camera) may be at least partially disposed in the opening to face the front surface 900A. In this case, the screen display area 901A may surround at least a portion of a periphery of the opening. According to an embodiment, the first camera 905 (e.g., an under display camera (UDC)) may be disposed under the display 901 to overlap with the area of the display 901. In such a circumstance, the display 901 may provide visual information to the user through the area, and additionally, the first camera 905 may obtain an image corresponding to the direction facing the front surface 900A through the area of the display 901.

The display 901 may be coupled with or disposed adjacent to a touch sensing circuit, a pressure sensor capable of measuring intensity (e.g., pressure) of a touch, and/or a digitizer for detecting a magnetic field type of stylus pen.

The audio modules may include microphone holes (e.g., a first microphone hole 903 and a second microphone hole 904) and a speaker hole 907.

The microphone holes may include a first microphone hole 903 formed in a partial area of the side surface 900C and a second microphone hole 904 formed in a partial area of the rear surface 900B. A microphone for obtaining external sound may be disposed in the microphone holes (e.g., the first microphone hole 903 and the second microphone hole 904). The microphone may include a plurality of microphones to detect a direction of sound.

The second microphone hole 904 formed in a partial area of the rear surface 900B may be disposed adjacent to the camera modules (e.g., a first camera 905, a second camera 912, and a flash 913). For example, the second microphone hole 904 may obtain sound according to the operation of the camera modules (e.g., the first camera 905, the second camera 912, and the flash 913). However, the present disclosure is not limited thereto.

The speaker hole 907 may include an external speaker hole and a call receiver hole. The external speaker hole (e.g., the speaker hole 907) may be formed in a part of the side surface 900C of the electronic device 101. According to an embodiment, the external speaker hole (e.g., the speaker hole 907) may be implemented as a single hole with the first microphone hole 903. According to some embodiments, the call receiver hole may be formed in another part of the side surface 900C. For example, the call receiver hole may be formed on the opposite side of the external speaker hole (e.g., the speaker hole 907) on the side surface 900C. For example, on the basis of illustration of FIG. 9A, the external speaker hole (e.g., the speaker hole 907) may be formed on the side surface 900C corresponding to the lower end of the electronic device 101, and the call receiver hole may be formed on the side surface 900C corresponding to the upper end of the electronic device 101. However, the present disclosure is not limited thereto, and the call receiver hole may be formed at a position other than the side surface 900C. For example, the call receiver hole may be formed by a space that is spaced apart between the front plate 902 (or the display 901) and the side bezel structure 918.

The electronic device 101 may include at least one speaker configured to output sound to the outside of the housing through the external speaker hole (e.g., the speaker hole 907) and/or the call receiver hole.

The sensor module may generate an electrical signal or data value corresponding to an operating state of the inside or an external environmental state of the electronic device 101. For example, the sensor module may include at least one from among a proximity sensor, a heart rate monitor (HRM) sensor, a fingerprint sensor, a gesture sensor, a gyro sensor, a barometric sensor, a magnetic sensor, an acceleration sensor, a grip sensor, a color sensor, an infrared (IR) sensor, a biometric sensor, a temperature sensor, a humidity sensor, and/or an illuminance sensor.

The camera modules may include a first camera 905 disposed to face in a same direction as a facing direction of the front (e.g., the front surface 900A) of the electronic device 101, a second camera 912 disposed to face in a same direction as a facing direction of the rear (e.g., the rear surface 900B), and a flash 913.

The second camera 912 may include a plurality of cameras (e.g., dual camera, triple camera, or quad camera). However, the second camera 912 is not limited to including a plurality of cameras, and may include a single camera.

The first camera 905 and the second camera 912 may include one or more lenses, an image sensor, and/or an image signal processor.

The flash 913 may include, for example, a light emitting diode or a xenon lamp. According to an embodiment, nine or more lenses (e.g., infrared cameras, wide-angle, and telephoto lenses) and image sensors may be disposed on one surface of the electronic device 101.

The key input device 917 may be disposed on the side surface 900C of the electronic device 101. According to an embodiment, the electronic device 101 may not include some or all of the key input devices 917, and the key input device 917 not included therein may be implemented in another form on the display 901, such as a soft key.

The connector hole 908 may be formed on the side surface 900C of the electronic device 101 so that a connector of an external device may be accommodated therein. A connector terminal electrically connected to the connector of the external device may be disposed in the connector hole 908. The electronic device 101 according to an embodiment may include an interface module for processing an electrical signal transmitted and received through the connector terminal.

The electronic device 101 may include a light emitting element. For example, the light emitting element may be disposed on the front surface 900A of the housing. The light emitting element may provide state information of the electronic device 101 in an optical form. For example, the light emitting element may provide a light source that is linked to an operation of the first camera 905. For example, the light emitting element may include a light-emitting diode (LED), an infrared (IR) LED, and/or a xenon lamp.

FIG. 9B is an exploded perspective view of an example electronic device.

Hereinafter, any redundant description of the configuration having the same reference numerals as those of the above-mentioned configurations may be omitted.

Referring to FIG. 9B, the electronic device 101 according to an embodiment may include a frame structure 940, a first printed circuit board 950, a second printed circuit board 952, a cover plate 960, and a battery 970.

The frame structure 940 may include a side bezel structure 918 forming an exterior of the electronic device 101 (e.g., the side surface 900C of FIG. 9A) and a support portion 943 extending inward from the side bezel structure 918. The frame structure 940 may be disposed between the display 901 and the rear plate 911. The side bezel structure 918 of the frame structure 940 may surround a space between the rear plate 911 and the front plate 902 (and/or the display 901), and the support portion 943 of the frame structure 940 may extend from the side bezel structure 918 within the space.

The frame structure 940 may support or accommodate other components included in the electronic device 101. For example, the display 901 may be disposed on one surface of the frame structure 940 facing in one direction (e.g., +z direction), and the display 901 may be supported by the support portion 943 of the frame structure 940. For example, the first printed circuit board 950, the second printed circuit board 952, the battery 970, and the second camera 912 may be disposed on the other surface facing an opposite direction (e.g., −z direction) to the one direction of the frame structure 940. The first printed circuit board 950, the second printed circuit board 952, the battery 970, and the second camera 912 may be respectively seated in recesses defined by the side bezel structure 918 and/or the support portion 943 of the frame structure 940. For example, the vapor chamber 500 illustrated and described with reference to FIGS. 5A to 8 may be disposed between the support portion 943 of the frame structure 940 and the display 901. However, embodiments of the present disclosure are not limited thereto, and the vapor chamber 500 may include, for example, a first portion 501 disposed between the first printed circuit board 950 and the support portion 943, a second portion 502 disposed between the battery 970 and the support portion 943, and a third portion 503 connecting the first portion 501 and the second portion 502, similar to the vapor chamber 500 illustrated and described with reference to FIGS. 5A to 8. However, embodiments of the present disclosure are not limited thereto.

The first printed circuit board 950, the second printed circuit board 952, and the battery 970 may be coupled to the frame structure 940. For example, the first printed circuit board 950 and the second printed circuit board 952 may be fixedly disposed on the frame structure 940 using a coupling member such as a screw. For example, the battery 970 may be fixedly disposed onto the frame structure 940 by means of an adhesive member (e.g., a double-sided tape), but the present disclosure is not limited to the above-described example.

The cover plate 960 may be disposed between the first printed circuit board 950 and the rear plate 911. According to an embodiment, the cover plate 960 may be disposed on the first printed circuit board 950. For example, the cover plate 960 may be disposed on a surface of the first printed circuit board 950 facing the −z direction.

The cover plate 960 may at least partially overlap with the first printed circuit board 950 with respect to the z-axis. According to an embodiment, the cover plate 960 may cover at least a partial area of the first printed circuit board 950. Accordingly, the cover plate 960 may protect the first printed circuit board 950 from a physical impact or prevent separation of the connector coupled to the first printed circuit board 950.

The cover plate 960 may be fixedly disposed on the first printed circuit board 950 by a coupling member (e.g., a screw), or may be coupled to the frame structure 940 together with the first printed circuit board 950 by means of the coupling member.

The display 901 may be disposed between the frame structure 940 and the front plate 902. For example, the front plate 902 may be disposed on one side (e.g., +z direction) of the display 901, and the frame structure 940 may be disposed on the other side (e.g., −z direction).

The front plate 902 may be coupled to the display 901. For example, the front plate 902 and the display 901 may be adhered to each other using an optical adhesive member (e.g., optically clear adhesive (OCA) or optically clear resin (OCR)) interposed therebetween.

The front plate 902 may be coupled to the frame structure 940. For example, the front plate 902 may include a peripheral portion extending out of the display 901 when viewed in the z-axis direction, and may be attached to the frame structure 940 through an adhesive member (e.g., a double-sided tape) disposed between the peripheral portion of the front plate 902 and the frame structure 940 (e.g., a side bezel structure 918). However, the present disclosure is not limited to the above-described example.

The first printed circuit board 950 and/or the second printed circuit board 952 may be equipped with a processor, a memory, and/or an interface. The processor may include, for example, one or more from among a central processing unit, an application processor, a graphics processing unit, an image signal processor, a sensor hub processor, and/or a communication processor. The memory may include, for example, volatile memory and/or non-volatile memory. The interface may include, for example, a high definition multimedia interface (HDMI), a universal serial bus (USB), an SD card interface, and/or an audio interface. The interface may electrically or physically connect the electronic device 101 to an external electronic device, and may include a USB connector, an SD card/MMC connector, or an audio connector. According to an embodiment, the first printed circuit board 950 and the second printed circuit board 952 may be operatively or electrically connected to each other via a connection member (e.g., a flexible printed circuit board).

The battery 970 may supply power to at least one component of the electronic device 101. For example, the battery 970 may include a rechargeable secondary battery or a fuel cell. At least a portion of the battery 970 may be disposed on substantially the same plane as the first printed circuit board 950 and/or the second printed circuit board 952.

The electronic device 101 may include an antenna module. The antenna module may be disposed between the rear plate 911 and the battery 970. The antenna module may include, for example, a near field communication (NFC) antenna, a wireless charging antenna, and/or a magnetic secure transmission (MST) antenna. The antenna module may, for example, perform short-range communication with an external device or wirelessly transmit and receive power to and from the external device.

The first camera 905 (e.g., front camera) may be disposed on at least a portion (e.g., the support portion 943) of the frame structure 940 so that the lens may receive external light through a partial area (e.g., the camera area 937) of the front plate 902 (e.g., the front surface 900A of FIG. 9A).

The second camera 912 (e.g., rear camera) may be disposed between the frame structure 940 and the rear plate 911. The second camera 912 may be electrically connected to the first printed circuit board 950 via a connection member (e.g., connector). According to an embodiment, the second camera 912 may be disposed such that the lens may receive external light through the camera area 984 of the rear plate 911 of the electronic device 101.

The camera area 984 may be formed on a surface of the rear plate 911 (e.g., the rear surface 900B of FIG. 9A). According to an embodiment, the camera area 984 may be formed to be at least partially transparent so that external light may be incident on the lens of the second camera 912. According to an embodiment, at least a portion of the camera area 984 may protrude from the surface of the rear plate 911 by a predetermined height. However, the present disclosure is not limited thereto, and the camera area 984 may be formed to be substantially the same plane as the surface of the rear plate 911.

The housing of the electronic device 101 (e.g., the housing 200 of FIG. 9A) may refer to a configuration or structure forming at least a part of the exterior of the electronic device 101. In this context, at least a part of the front plate 902, the frame structure 940, and/or the rear plate 911 forming the exterior of the electronic device 101 may be referred to as the housing 200 of the electronic device 101.

According to the above description, an electronic device (e.g., the electronic device 101 of FIG. 1) may include a bracket (e.g., the first bracket 215 of FIG. 2C, the bracket 410 of FIG. 4) including a mounting portion (e.g., the mounting portion 411 of FIG. 4C), a printed circuit board (e.g., the printed circuit board 430 of FIG. 4) disposed toward the bracket, a heat generating component (e.g., the processor 120 of FIG. 1, the electronic component 401 of FIG. 4) disposed on one surface (e.g., one surface 430a of FIG. 5B) facing toward the bracket of the printed circuit board, a battery (e.g., the battery 264 of FIG. 2C) spaced apart from the heat generating component and accommodated in the bracket, and a vapor chamber (e.g., the vapor chamber 500 of FIG. 5A) mounted on the mounting portion of the bracket. The vapor chamber may include a first portion (e.g., the first portion 501 of FIG. 5A) disposed on the heat generating component, a second portion (e.g., the second portion 502 of FIG. 5A) interposed between the battery and the mounting portion, and a third portion (e.g., the third portion 503 of FIG. 5A) extending from the first portion to the second portion.

For example, the vapor chamber may be configured to diffuse heat transferred from the heat generating component to the first part, through the third portion, to the second portion.

For example, an area (e.g., A2 of FIG. 5A) of the second portion of the vapor chamber may be greater than an area (e.g., A1 of FIG. 5A) of the first portion of the vapor chamber.

For example, the electronic device may further include a display (e.g., the display 230 of FIG. 2A) disposed on the bracket. The vapor chamber may be separated or isolated from the display by the bracket.

For example, the electronic device may include a housing (e.g., the housing 200 of FIG. 2A) including a first housing part (e.g., the first housing part 210 of FIG. 2A) defining the bracket and a second housing part (e.g., the second housing 220 of FIG. 2A), and a hinge assembly (e.g., the hinge structure 250 of FIG. 2B) rotatably coupling the first housing part and the second housing part. The display may include a first planar portion (e.g., the first planar portion 231 of FIG. 2A) coupled to the first housing part and disposed on the mounting portion of the bracket, a second planar portion (e.g., the second planar portion 232 of FIG. 2A) coupled to the second housing part and spaced apart from the first planar portion, and a foldable portion (e.g., the foldable portion 233 of FIG. 2A) extending from the first planar portion to the second planar portion and configured to be deformable by the hinge assembly.

For example, the electronic device may further include a heat dissipation member (e.g., the heat dissipation member 800 of FIG. 8) extending from the second portion of the vapor chamber, across the hinge assembly, to an inside of the second housing part.

For example, the vapor chamber may include: an enclosure (e.g., the enclosure 510 of FIG. 5C) including a first plate (e.g., the first plate 511 of FIG. 5C) attached to the mounting portion, and a second plate (e.g., the second plate 512 of FIG. 5C) coupled to the first plate and attached to the battery; a fluid in the enclosure; and a wick structure (e.g., the wick structure 520 of FIG. 5C) disposed in the enclosure and contacting the second plate. The second plate may include a plurality of flow paths (e.g., a plurality of flow paths 700 of FIG. 7A) that are recessed from a bottom surface of the second plate to move the fluid in a liquid state between the second plate and the wick structure.

For example, the second plate may include corner portions (e.g., the corner portions 720 of FIG. 7C) disposed along a periphery of the second plate, and a center portion (e.g., the center portion 710 of FIG. 7C) surrounded by the corner portions. The plurality of flow paths may include first flow paths (e.g., the first flow paths 701 of FIG. 7C) formed in the center portion and having a first pattern (e.g., p1 of FIG. 7C), and second flow paths (e.g., the second flow paths 702 of FIG. 7C) formed in the corner portions and connected to the first flow paths, at least some of the second flow paths having a second pattern (e.g., p2 of FIG. 7C) different from the first pattern.

For example, the second pattern may have a radial pattern.

For example, the plurality of flow paths may include one or more third flow paths (e.g., one or more third flow paths 703 of FIG. 7C) formed along a periphery of the second plate and configured to circulate the fluid in a liquid state along the periphery of the second plate, and one or more fourth flow path (e.g., one or more fourth flow paths 704 of FIG. 7C) providing a passage for connecting at least some of the second flow paths and the one or more third flow paths.

For example, the vapor chamber may include an enclosure including a first plate attached to the mounting portion, and a second plate coupled to the first plate and attached to the battery. The electronic device may further include an adhesive member (e.g., the adhesive member 550 of FIG. 5C) disposed between the second plate and the battery.

For example, the second plate included in the second portion may include an adhesive surface (e.g., the adhesive surface 502a of FIG. 6C) on which the adhesive member is attached, and a protruding surface (e.g., the protruding surface 502b of FIG. 6C) protruding from the adhesive surface toward the battery to be in contact with the battery.

For example, the first plate may include a plurality of pillars (e.g., a plurality of pillars 530 of FIG. 5C) protruding from the first plate toward the second plate within the enclosure, at least some of plurality of pillars being welded to the second plate.

For example, the electronic device may further include a fastener (e.g., a fastener 600 of FIG. 6C) disposed on the third portion of the vapor chamber and coupled to the bracket to fasten the vapor chamber to the bracket.

For example, a thickness (e.g., thickness t1 of FIG. 6C) of the first portion of the vapor chamber is greater than a thickness (e.g., thickness t2 of FIG. 6C) of the second portion of the vapor chamber.

According to the above description, an electronic device may include a bracket including a mounting portion, a printed circuit board (PCB) disposed toward the bracket, a heat generating component disposed on a surface of the PCB facing toward the bracket, a shield can (e.g., the shield can 440 of FIG. 5B) disposed on the surface of the PCB, including a through hole (e.g., through hole 445 of FIG. 5B), and surrounding the heat generating component, a shielding sheet (e.g., the shielding sheet 450 of FIG. 5B) attached on the shield can to cover the through hole, a heat conduction member (e.g., the heat conduction member 460 of FIG. 5C) interposed between the heat generating component and the shielding sheet through the through hole of the shield can, a battery spaced apart from the heat generating component and accommodated in the bracket, and a vapor chamber mounted to the mounting portion of the bracket. The vapor chamber may include a first portion attached to the shielding sheet, a second portion interposed between the mounting portion and the battery, and a third portion extending from the first portion to the second portion.

For example, the vapor chamber may be configured to spread heat received to the first portion from the heat generating component, through the third portion, to the second portion. An area of the second portion of the vapor chamber may be greater than an area of the first portion of the vapor chamber.

For example, the vapor chamber may include an enclosure including a first plate attached to the mounting portion, and a second plate, coupled to the first plate, attached to the battery, and defining corner portions and a center portion surrounded by the corner portions, a fluid in the enclosure, and a wick structure disposed in the enclosure and contacting the second plate. The second plate may include a plurality of flow paths recessed from a bottom surface of the second plate to move the fluid in a liquid state between the second plate and the wick structure. The plurality of flow paths may include first flow paths formed in the center portion and having a first pattern, and second flow paths formed in the corner portions and connected to the first flow paths, at least of the second flow paths having a second pattern different from the first pattern, the second pattern having a radial pattern.

For example, the plurality of flow paths may include one or more third flow paths formed along a periphery of the second plate and configured to circulate the fluid in a liquid state along the periphery of the second plate, and one or more fourth flow paths providing a passage between at least some of the second flow paths and the one or more third flow paths.

For example, the electronic device may further include an adhesive member disposed between the vapor chamber and the battery. The second portion may include an adhesive surface on which the adhesive member is attached, and a protruding surface coming into contact with the battery by protruding from the adhesive surface toward the battery.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment, the electronic devices are not limited to those described above.

It should be appreciated that various embodiments and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively,” as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the present disclosure, the term “module” may include a unit implemented in hardware, software, or firmware, and may be interchangeably used with other terms, for example, “logic,” “logic block,” “part,” “portion,” or “circuit.” A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., an internal memory 136 or an external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments disclosed herein may be included and provided in a computer program product. The computer program product may be traded as a product between a seller and a buyer. The computer program product may be distributed in the form of a machine-readable storage medium (e.g., a compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

No claim element is to be construed under the provisions of 35 U.S.C. § 112, sixth paragraph, unless the element is expressly recited using the phrase “means for” or “means.”

What is claimed is:

1. An electronic device comprising:
a bracket comprising a mounting portion;
a printed circuit board (PCB) disposed on the bracket;
a heat generating component, disposed on a surface of the PCB, the surface of the PCB facing the bracket;
a battery, spaced apart from the heat generating component, accommodated in the bracket; and
a vapor chamber on the mounting portion of the bracket,
wherein the vapor chamber comprises:
a first portion disposed above the heat generating component,
a second portion interposed between the mounting portion and the battery, and
a third portion extending from the first portion of the vapor chamber to the second portion of the vapor chamber.

2. The electronic device of claim 1,
wherein the vapor chamber is configured to spread heat, transferred from the heat generating component to the first portion, to the second portion through the third portion.

3. The electronic device of claim 1,
wherein an area of the second portion is greater than an area of the first portion.

4. The electronic device of claim 1, further comprising a display disposed on the bracket,
wherein the vapor chamber is separated from the display by the bracket.

5. The electronic device of claim 4, further comprising:
a housing comprising:
a first housing part defining the bracket, and
a second housing part; and
a hinge assembly rotatably connecting the first housing part and the second housing part,
wherein the display comprises:
a first flat portion, coupled to the first housing part, disposed on the mounting portion of the bracket,
a second flat portion, coupled to the second housing part, spaced apart from the first flat portion, and
a foldable portion, extending from the first flat portion to the second flat portion, configured to be deformed by the hinge assembly.

6. The electronic device of claim 5, further comprising a heat dissipation member extending from the second portion of the vapor chamber, across the hinge assembly, to an inside of the second housing part.

7. The electronic device of claim 1,
wherein the vapor chamber comprises:
an enclosure comprising:
a first plate attached to the mounting portion, and
a second plate, coupled to the first plate, attached to the battery, a fluid in the enclosure, and
a wick structure, disposed in the enclosure, contacting the second plate, and
wherein the second plate comprises a plurality of flow paths, recessed from a bottom surface of the second plate to move the fluid in a liquid state between the second plate and the wick structure.

8. The electronic device of claim 7,
wherein the second plate comprises:
corner portions disposed along a periphery of the second plate, and
a center portion surrounded by the corner portions,
wherein the plurality of flow paths comprise:
first flow paths, formed in the center portion, having a first pattern, and
second flow paths, formed in at least some of the corner portions, connecting to the first flow paths, having second pattern different from the first pattern.

9. The electronic device of claim 8,
wherein the second pattern is a radial pattern.

10. The electronic device of claim 8,
wherein the plurality of flow paths comprise:
one or more third flow paths, formed along the periphery of the second plate, configured to circulate the fluid in the liquid state along the periphery of the second plate, and
one or more fourth flow paths that are configured function as a passage between at least one from among the first flow paths and the second flow paths and the one or more third flow paths.

11. The electronic device of claim 1,
wherein the vapor chamber comprises an enclosure comprising:
a first plate attached to the mounting portion, and
a second plate, coupled to the first plate, attached to the battery, and
wherein the electronic device further comprises an adhesive member disposed between the second plate and the battery.

12. The electronic device of claim 11,
wherein a portion of the second plate is in the second portion, and the portion of the second plate comprises:
an adhesive surface on which the adhesive member is attached, and
a protruding surface contacting the battery by protruding from the adhesive surface toward the battery.

13. The electronic device of claim 11,
wherein the first plate includes a plurality of pillars, protruding from the first plate toward the second plate within the enclosure, at least some of which are welded to the second plate.

14. The electronic device of claim 1, further comprising a fastener, disposed on the third portion of the vapor chamber, configured to fasten the vapor chamber to the bracket.

15. The electronic device of claim 1,
wherein a thickness of the first portion of the vapor chamber is thicker than a thickness of the second portion of the vapor chamber.

16. An electronic device comprising:
a bracket comprising a mounting portion;
a printed circuit board (PCB) overlapping with the bracket;
a heat generating component on a surface of the PCB, the surface facing toward the bracket;
a shield can on the surface of the PCB, the shield can including a through hole and the shield can surrounding the heat generating component;
a shielding sheet covering the through hole and connected to the shield can;
a heat conduction member in the through hole and between the heat generating component and the shielding sheet;
a battery spaced apart from the heat generating component, accommodated in the bracket; and
a vapor chamber on the mounting portion of the bracket,
wherein the vapor chamber comprises:
a first portion above the heat generating component,
a second portion between the mounting portion and the battery, and
a third portion extending from the first portion to the second portion.

17. The electronic device of claim 16,
wherein the vapor chamber is configured to spread heat received by the first portion from the heat generating component to the second portion through the third portion, and
wherein an area of the second portion is greater than an area of the first portion.

18. The electronic device of claim 16,
wherein the vapor chamber comprises:
an enclosure comprising:
a first plate connected to the mounting portion; and
a second plate connected to the first plate and the battery, and the second plate comprising corner portions and a center portion surrounded by the corner portions,
a fluid in the enclosure, and
a wick structure in the enclosure and contacting the second plate,
wherein the second plate comprises a plurality of flow paths that are recessed in a bottom surface of the second plate, the plurality of flow paths configured to move the fluid in a liquid state between the second plate and the wick structure, and
wherein the plurality of flow paths comprise:
first flow paths in the center portion and comprising a first pattern, and
second flow paths in at least some of the corner portions and connecting to the first flow paths, the second flow paths comprising a second pattern that is a radial pattern, the second pattern being different from the first pattern.

19. The electronic device of claim 18,
wherein the plurality of flow paths further comprise:
one or more third flow paths along a periphery of the second plate, the one or more third flow paths configured to circulate the fluid in the liquid state along the periphery of the second plate, and
one or more fourth flow paths configured as a passage between at least one from among the first flow paths and the second flow paths and the one or more third flow paths.

20. The electronic device of claim 16, further comprising an adhesive member between the vapor chamber and the battery,
wherein the second portion comprises:
an adhesive surface on which the adhesive member is connected, and
a protruding surface contacting the battery by protruding from the adhesive surface toward the battery.
